(19) United States
(12) Patent Application Publication
(10) Pub. No.: US 2020/0063260 A1
(43) Pub. Date: Feb. 27, 2020

(54) ATOMIC LAYER DEPOSITION APPARATUS AND FILM-FORMING METHOD

(71) Applicant: THE JAPAN STEEL WORKS, LTD., Tokyo (JP)

(72) Inventors: Keisuke WASHIO, Kanagawa (JP); Toru MASHITA, Kanagawa (JP)

(21) Appl. No.: 16/538,043

(22) Filed: Aug. 12, 2019

(30) Foreign Application Priority Data
Aug. 22, 2018 (JP) 2018-155416

(51) Int. Cl. C23C 16/455; H01L 21/02; C23C 16/44; H01L 21/687

(52) U.S. Cl. CPC C23C 16/45544; H01L 21/0228; H01L 21/02175; C23C 16/4412; C23C 16/4401; H01L 21/68742; C23C 16/45536

(57) ABSTRACT

An atomic layer deposition apparatus includes a chamber, a stage which is disposed in the chamber and over which a substrate is placed, an opening which is provided in a side wall of the chamber, an opening and closing part which is connected to the opening, and a movable adhesion preventing member disposed in the chamber. The opening is an opening for transferring the substrate. The adhesion preventing member is located at a position where it covers the opening in a state where the opening and closing part is closed.

### CROSS-REFERENCE TO RELATED APPLICATION

The present application claims priority from Japanese Patent Application No. 2018-155416 filed on Aug. 22, 2018, the content of which is hereby incorporated by reference into this application.

### TECHNICAL FIELD OF THE INVENTION

The present invention relates to an atomic layer deposition apparatus and a film-forming method.

### BACKGROUND OF THE INVENTION

There is the atomic layer deposition method as a method for forming a film over a substrate. In the atomic layer deposition method, a film is formed over a substrate in a unit of atomic layer by alternately supplying source gas and reaction gas to the substrate.

Japanese Patent Application Laid-Open Publication No. 2018-037508 (Patent Document 1) describes a technology relating to an atomic layer deposition apparatus.

### SUMMARY OF THE INVENTION

The atomic layer deposition apparatus forms a film in a unit of atomic layer, and thus is excellent in step coverage and film thickness controllability. On the other hand, however, there is a concern that the film may be formed also at a place where removal thereof is difficult. Therefore, in the atomic layer deposition apparatus, there is a concern that generation of a foreign matter caused by peeling of the film formed at the place where removal thereof is difficult may deteriorate the quality of the film formed over the substrate.

Other problems and novel features of the present invention will be apparent from the description of the present specification and the accompanying drawings.

According to an embodiment, an atomic layer deposition apparatus includes a chamber, a stage which is disposed in the chamber and over which a substrate is placed, an opening which is provided in a side wall of the chamber, an opening and closing part which is connected to the opening, and a movable first adhesion preventing member disposed in the chamber. The opening is an opening for transferring the substrate. The first adhesion preventing member is located at a position where it covers the opening in a state where the opening and closing part is closed.

According to an embodiment, a film-forming method includes the steps of (a) loading a substrate into a chamber through an opening of the chamber, (b) closing an opening and closing part disposed outside the chamber and connected to the opening, (c) moving an adhesion preventing member disposed in the chamber to a position where it covers the opening; and (d) forming a film over the substrate in the chamber by an atomic layer deposition method.

According to an embodiment, it is possible to improve the quality of the film formed over the substrate.

### BRIEF DESCRIPTIONS OF THE DRAWINGS

FIG. 1 is a cross-sectional view schematically showing a film-forming apparatus according to an embodiment;

FIG. 2 is a cross-sectional view schematically showing the film-forming apparatus according to the embodiment;

FIG. 3 is a cross-sectional view schematically showing the film-forming apparatus according to the embodiment;

FIG. 4 is a cross-sectional view of a chamber of the film-forming apparatus according to the embodiment;

FIG. 5 is a cross-sectional view of the chamber of the film-forming apparatus according to the embodiment;

FIG. 6 is a cross-sectional view of the chamber of the film-forming apparatus according to the embodiment;

FIG. 7 is a process flowchart showing a film-forming process using the film-forming apparatus according to the embodiment;

FIG. 8 is an explanatory diagram showing the film-forming process using the film-forming apparatus according to the embodiment;

FIG. 9 is an explanatory diagram showing the film-forming process continued from FIG. 8;

FIG. 10 is an explanatory diagram showing the film-forming process continued from FIG. 9;

FIG. 11 is an explanatory diagram showing the film-forming process continued from FIG. 10;

FIG. 12 is an explanatory diagram showing the film-forming process continued from FIG. 11;

FIG. 13 is an explanatory diagram showing the film-forming process continued from FIG. 12;

FIG. 14 is an explanatory diagram showing the film-forming process continued from FIG. 13;

FIG. 15 is an explanatory diagram showing the film-forming process continued from FIG. 14;

FIG. 16 is an explanatory diagram showing the film-forming process continued from FIG. 14 and FIG. 15;

FIG. 17 is an explanatory diagram showing the film-forming process continued from FIG. 16;

FIG. 18 is an explanatory diagram showing the film-forming process continued from FIG. 17;

FIG. 19 is an explanatory diagram showing the film-forming process continued from FIG. 18;

FIG. 20A to FIG. 20E are explanatory diagrams of a film-forming step in the film-forming process;

FIG. 21 is an explanatory diagram showing the film-forming process continued from FIG. 19;

FIG. 22 is an explanatory diagram showing the film-forming process continued from FIG. 21;

FIG. 23 is an explanatory diagram showing the film-forming process continued from FIG. 22;

FIG. 24 is an explanatory diagram showing the film-forming process continued from FIG. 23;

FIG. 25 is an explanatory diagram showing the film-forming process continued from FIG. 24; and

FIG. 26 is an explanatory diagram showing the film-forming process continued from FIG. 25.

### DESCRIPTIONS OF THE PREFERRED EMBODIMENTS

Hereinafter, embodiments of the present invention will be described in detail with reference to drawings. Note that components having the same function are denoted by the same reference characters throughout the drawings for describing the embodiments, and the repetitive description thereof will be omitted. Also, in the following embodiments, descriptions of the same or similar components will not be repeated in principle unless otherwise required.

### Embodiment

### Overall Configuration of Film-Forming Apparatus

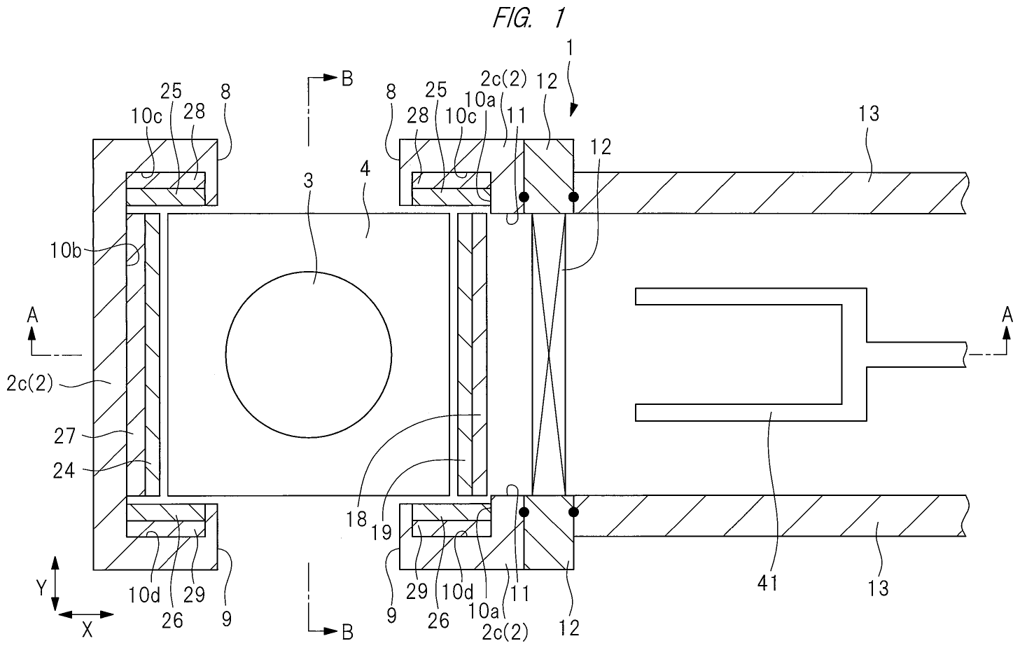

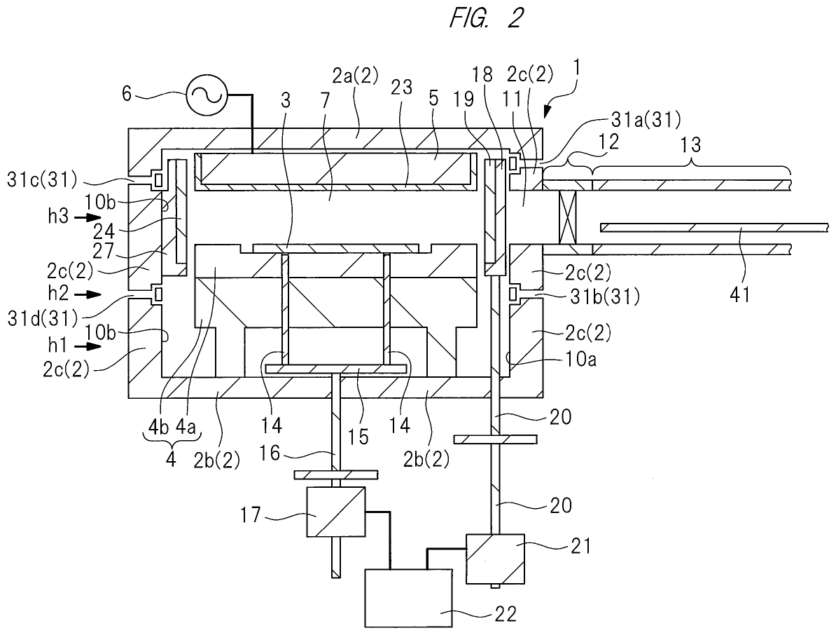

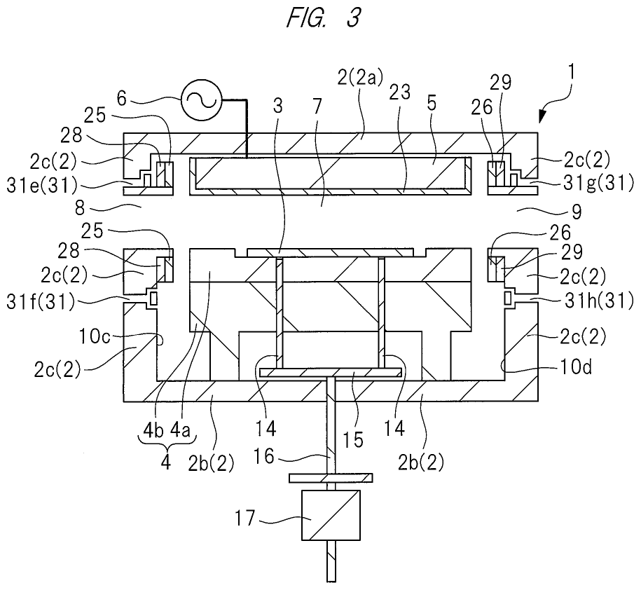

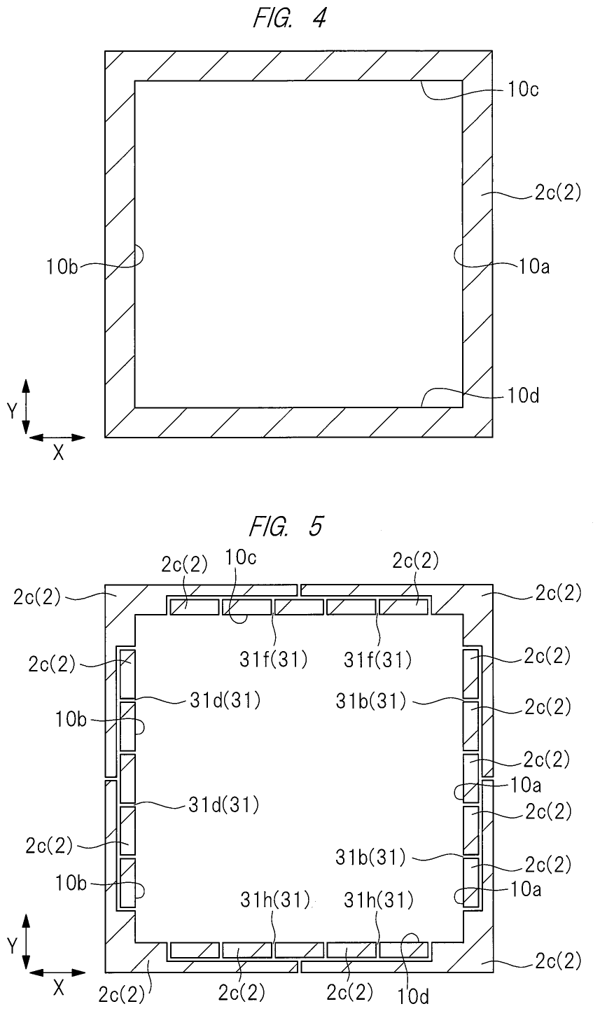

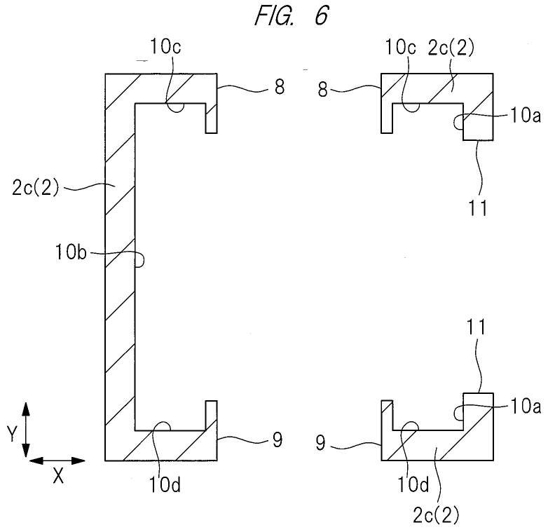

An overall configuration of a film-forming apparatus 1 according to this embodiment will be described with reference to FIG. 1 to FIG. 6. FIG. 1 to FIG. 3 are cross-sectional views schematically showing the overall configuration of the film-forming apparatus 1 according to this embodiment. FIG. 1 shows a cross section (horizontal section) substantially parallel to an upper surface of a stage 4 (upper surface of susceptor 4a) of the film-forming apparatus 1, and FIG. 2 and FIG. 3 each show a cross section (vertical section) substantially vertical to the upper surface of the stage 4 of the film-forming apparatus 1. The cross section at the position of a line A-A of FIG. 1 almost corresponds to FIG. 2 and the cross section at the position of a line B-B of FIG. 1 almost corresponds to FIG. 3. Also, FIG. 4 to FIG. 6 are cross-sectional views of a chamber 2 of the film-forming apparatus 1 and show only the chamber. FIG. 4 to FIG. 6 are cross sections substantially parallel to the upper surface of the stage 4, but differ in the height positions of the cross sections. The cross section of the chamber 2 at a height position h1 indicated by an arrow in FIG. 2 almost corresponds to FIG. 4, the cross section of the chamber 2 at a height position h2 indicated by an arrow in FIG. 2 almost corresponds to FIG. 5, and the cross section of the chamber 2 at a height position h3 indicated by an arrow in FIG. 2 almost corresponds to FIG. 6. The cross section of FIG. 1 almost corresponds to the cross section at the height position h3 indicated by the arrow in FIG. 2 as with FIG. 6. Note that an X direction and a Y direction shown in FIG. 1 and FIG. 4 to FIG. 6 are directions substantially parallel to the upper surface of the stage 4 of the film-forming apparatus 1, and the X direction and the Y direction are orthogonal to each other.

The film-forming apparatus (atomic layer deposition apparatus) 1 is a film-forming apparatus that forms a film by the ALD (Atomic Layer Deposition) method, and can be regarded as an ALD apparatus (atomic layer deposition apparatus) or an ALD film-forming apparatus. Also, in this embodiment, the case in which the plasma ALD apparatus (plasma atomic layer deposition apparatus) that forms a film by the plasma ALD method is used as the film-forming apparatus 1 will be described. In the plasma ALD apparatus, in order to enhance the reaction activity, plasma discharge is performed to convert the reaction gas into plasma. Therefore, in the plasma ALD apparatus, a parallel plate electrode and the like are used to perform the plasma discharge.

Hereinafter, the overall configuration of the film-forming apparatus 1 will be specifically described.

As shown in FIG. 1 to FIG. 6, the film-forming apparatus 1 includes the chamber (film-forming chamber, film-forming container) 2 in which film formation (film-forming step) by the ALD method is performed. The chamber 2 is a film-forming container (chamber) for performing the film-forming step to a substrate 3 placed in the chamber. The chamber 2 has a top plate 2a, a bottom plate 2b, and a side wall part 2c connecting (linking) the top plate 2a and the bottom plate 2b. The top plate 2a forms an upper surface of the chamber 2, the bottom plate 2b forms a bottom surface of the chamber 2, and the side wall part 2c forms side surfaces of the chamber 2.

In this embodiment, “the upper surface of the chamber 2” refers to “the upper surface on the inner side (inner surface) of the chamber 2”, “the side surface of the chamber 2” refers to “the side surface on the inner side (inner surface) of the chamber 2”, and “the bottom surface of the chamber 2” refers to “the bottom surface on the inner side (inner surface) of the chamber 2”.

Also, FIG. 1 to FIG. 6 show the case in which the chamber 2 has a substantially rectangular planar shape. In this case, the chamber 2 has four side surfaces 10a, 10b, 10c, and 10d, the side surfaces 10a and 10b face each other, and the side surfaces 10c and 10d face each other. The side surfaces 10a and 10c form a corner portion, the side surfaces 10a and 10d form a corner portion, the side surfaces 10b and 10c form a corner portion, and the side surfaces 10b and 10d form a corner portion. The side surfaces 10a, 10b, 10c, and 10d of the chamber 2 are formed by the side wall part 2c of the chamber 2, in other words, the side wall part 2c of the chamber 2 has a pair of side surfaces 10a and 10b facing each other and a pair of side surfaces 10c and 10d facing each other. Each of the side surfaces 10a and 10b is substantially perpendicular to the X direction and substantially parallel to the Y direction. Further, each of the side surfaces 10c and 10d is substantially perpendicular to the Y direction and substantially parallel to the X direction. The side surfaces 10a and 10b and the side surfaces 10c and 10d are orthogonal to each other. Namely, the side surface 10a is orthogonal to each of the side surfaces 10c and 10d, and the side surface 10b is orthogonal to each of the side surfaces 10c and 10d. As another embodiment, the chamber 2 may have a circular planar shape.

In the chamber 2, the stage 4 for placing (mounting) the substrate 3 to be processed is provided. The stage 4 has a susceptor (substrate holder) 4a for holding the substrate 3 and a stage main body 4b for supporting the susceptor 4a. The stage main body 4b is disposed over the bottom plate 2b of the chamber 2 and is fixed to the bottom plate 2b. The susceptor 4a is disposed and supported (held) over the stage main body 4b. The substrate 3 is placed and held over the susceptor 4a. The susceptor 4a has conductivity. The stage 4 (more specifically, the susceptor 4a) also has a function as a lower electrode. Further, the stage 4 includes a heater (not shown) and the like, so that the substrate 3 placed over the stage 4 can be heated and the temperature of the substrate 3 can be adjusted to a desired temperature. For example, the substrate 3 held over the stage 4 is heated to about 50 to 200° C. during the film-forming step. Although various substrates can be used as the substrate 3, for example, a semiconductor substrate, a glass substrate, a flexible substrate, or the like can be used.

In this embodiment, the combination of the stage main body 4b and the susceptor 4a is regarded as the stage 4. In another aspect, however, the stage main body 4b may be regarded as the stage, and the substrate 3 may be regarded as being placed over the susceptor 4a disposed over the stage.

In the chamber 2, an upper electrode (parallel plate electrode) 5 is disposed above the stage 4 (susceptor 4a). In the chamber 2, the upper electrode 5 is disposed above the stage 4 (susceptor 4a), and is thus disposed above the substrate 3 placed over the stage 4. Therefore, in the chamber 2, the upper electrode 5 is disposed so as to face the stage 4 (susceptor 4a). The upper electrode 5 and the susceptor 4a face each other, and the substrate 3 is placed over a main surface (upper surface) of the susceptor 4a on a side facing the upper electrode 5. The upper electrode 5 and a lower electrode (in this case, the susceptor 4a) form the parallel plate electrode. The upper electrode 5 is supported (held) over the top plate 2a of the chamber 2.

A high frequency power supply 6 is electrically connected to the upper electrode 5. The high frequency power supply 6 can apply a high frequency power to the upper electrode 5, that is, between the upper electrode 5 and the stage 4 (more specifically, the susceptor 4a), so that a high frequency electric field can be generated between the upper electrode 5 and the stage 4 (more specifically, the susceptor 4a). The susceptor 4a is preferably connected to the ground potential. A space 7 between the upper electrode 5 and the stage 4 (susceptor 4a) is a space (discharge space, plasma discharge space, plasma generation space) in which plasma (plasma discharge) is generated. The high frequency power supply 6 can be disposed outside the chamber 2. When an adhesion preventing member 23 described later is attached to the upper electrode 5, the space 7 can also be regarded as a space between the adhesion preventing member 23 and the stage 4 (susceptor 4a).

Also, the chamber 2 includes a gas introduction part (gas supply part, gas introduction opening, opening) 8 for introducing (supplying) gas into the chamber 2 and a gas exhaust part (gas discharge part, exhaust opening, opening) 9 for exhausting (discharging) the gas from inside of the chamber 2. The gas introduction part 8 and the gas exhaust part 9 are both provided in the side wall part 2c of the chamber 2. The gas introduced into the chamber 2 through the gas introduction part 8 is source gas, purge gas, and reaction gas. The gas exhaust part 9 of the chamber 2 is connected to a vacuum pump (not shown) or the like through piping, so that the gas can be exhausted (discharged) from the inside of the chamber 2 through the gas exhaust part 9 and the pressure of the inside of the chamber 2 can be controlled to a predetermined pressure. Namely, the inside of the chamber 2 can be maintained at a vacuum or can be controlled to a desired pressure.

Each of the gas introduction part 8 and the gas exhaust part 9 is an opening provided in the side wall part 2c, and the gas introduction part 8 and the gas exhaust part 9 are provided at the positions facing each other (in this case, positions facing in the Y direction) in the side wall part 2c of the chamber 2. Specifically, the gas introduction part 8 is provided in one side surface (here, the side surface 10c) of the side surfaces 10c and 10d facing each other of the chamber 2, and the gas exhaust part 9 is provided in the other side surface (here, the side surface 10d). Namely, the opening constituting the gas introduction part 8 penetrates the side wall part 2c that forms the side surface 10c of the chamber 2, and the opening constituting the gas exhaust part 9 penetrates the side wall part 2c that forms the side surface 10d of the chamber 2. It is preferable that at least a part of the gas introduction part 8 and the gas exhaust part 9 is located at the same height position as the space 7 between the upper electrode 5 and the stage 4 (susceptor 4a).

The gas (source gas, purge gas, reaction gas) introduced through the gas introduction part 8 passes through the space 7 in the chamber 2, and is exhausted through the gas exhaust part 9. Namely, since the gas introduced into the chamber 2 through the gas introduction part 8 flows from the gas introduction part 8 to the gas exhaust part 9, the gas passes through the space 7 between the gas introduction part 8 and the gas exhaust part 9. Therefore, in the film-forming step (step S2 described later), the source gas, the purge gas, and the reaction gas can be supplied to (pass through) the space 7.

In addition, the chamber 2 is provided with an opening (substrate transfer opening) 11 for taking in and out the substrate 3. The opening 11 is provided in the side wall part 2c of the chamber 2. Specifically, the opening 11 is provided in the side surface 10a of the chamber 2. Namely, the opening 11 penetrates the side wall part 2c that forms the side surface 10a of the chamber 2. The opening 11 is an opening for transferring the substrate 3, and the substrate 3 is loaded into the chamber 2 through the opening 11 and the substrate 3 is unloaded to the outside of the chamber 2 through the opening 11. At least a part of the opening 11 of the chamber 2 is located at the same height position as the space 7 between the upper electrode 5 and the stage 4 (susceptor 4a).

An opening and closing part (opening and closing mechanism, gate valve) 12 is connected to the opening 11 of the chamber 2. The opening and closing part 12 is disposed outside the chamber 2. For example, a gate valve can be suitably used as the opening and closing part 12. The opening and closing part 12 can be switched between an open state (a state in which the opening and closing part 12 is opened) and a closed state (a state in which the opening and closing part 12 is closed). If the opening and closing part 12 is in the open state, solid and gas can pass through the opening and closing part 12. If the opening and closing part 12 is in the closed state, solid and gas cannot pass through the opening and closing part 12. A substrate transfer path (transfer chamber) 13 is connected (linked) to the opening 11 via the opening and closing part 12. Namely, the opening and closing part 12 is present between the opening 11 and the substrate transfer path 13. The chamber 2 and the substrate transfer path 13 are partitioned by the opening and closing part 12. The substrate transfer path 13 is disposed outside the chamber 2.

The opening and closing part 12 can be switched between the open state and the closed state, and thus can control the substantial opening and closing of the opening 11. Namely, when the opening and closing part 12 is in the closed state, the opening 11 is closed (blocked) by the opening and closing part 12 in the closed state, and thus the space in the chamber 2 and the space of the substrate transfer path 13 are separated by the opening and closing part 12 in the closed state (in a state in which they are not connected continuously). In this state, it is not possible to move the solid (for example, the substrate 3) and gas between the inside of the chamber 2 and the substrate transfer path 13.

Meanwhile, when the opening and closing part 12 is in the open state, the opening 11 is not closed (not blocked) by the opening and closing part 12, and the space in the chamber 2 and the space of the substrate transfer path 13 are continuously connected via the opening 11 and the opening and closing part 12 in the open state. In this state, it is possible to move the solid (for example, the substrate 3) and gas between the inside of the chamber 2 and the substrate transfer path 13 through the opening 11 and the opening and closing part 12 in the open state.

As described above, although the shape of the opening 11 provided in the side wall of the chamber 2 is not changed, the substantial opening and closing of the opening 11 can be controlled by switching the open state and the closed state of the opening and closing part 12 connected to the opening 11.

The substrate transfer path 13 is a path (space) used for loading and unloading the substrate 3. The substrate transfer path 13 may be a transfer path (transfer space) connecting the opening and closing part 12 and the transfer chamber, but the substrate transfer path 13 itself may be the transfer chamber. The substrate 3 can be loaded into the chamber 2 from the substrate transfer path 13 through the opening and closing part 12 in the open state and the opening 11, and the substrate 3 can be unloaded from the chamber 2 to the substrate transfer path 13 through the opening 11 and the opening and closing part 12 in the open state.

The film-forming apparatus 1 includes lift pins (pins, raising and lowering pins) 14 which penetrate the susceptor 4a and can move vertically (raising and lowering movement) in the chamber 2. The susceptor 4a and the stage main body 4b have holes (through holes) for the lift pins 14, and the lift pins 14 are inserted through the holes. The lift pins 14 can vertically move the substrate 3 (raising and lowering movement). The lift pins 14 are used to lift the substrate 3 from the stage 4 (susceptor 4a) and transfer the substrate 3 to a substrate loading/unloading height position in the chamber 2.

It is preferable that a plurality of lift pins 14 are provided, and it is more preferable to provide three or more lift pins 14 so that the substrate 3 can be moved stably. Lower ends of the plurality of lift pins 14 are coupled to a common support member 15, and a shaft 16 is coupled to the support member 15.

The film-forming apparatus 1 includes a driving mechanism (raising and lowering mechanism, operating mechanism, driving unit) 17 for raising and lowering the lift pins 14 (vertical movement, raising and lowering movement), and the shaft 16 is connected to the driving mechanism 17. The driving mechanism 17 is provided outside the chamber 2. By moving the shaft 16 vertically by the driving mechanism 17, the support member 15 coupled to the shaft 16 can be moved vertically, so that the plurality of lift pins 14 coupled to the support member 15 can be moved vertically. Note that a part of the shaft 16 located outside the chamber 2 can pass through a bellows tube (not shown).

The lift pins 14 can move vertically between a lowered position (the position where the lift pins 14 are lowered) and a raised position (the position where the lift pins 14 are raised). When the lift pins 14 are at the lowered position, the tops (upper surfaces) of the lift pins 14 are at the same height position as the upper surface of the susceptor 4a or lower than the upper surface of the susceptor 4a, and thus the lift pins 14 do not protrude from the upper surface of the susceptor 4a. When the lift pins 14 are at the raised position, the tops (upper surfaces) of the lift pins 14 are higher than the upper surface of the susceptor 4a, and the lift pins 14 protrude from the upper surface of the susceptor 4a. In this embodiment, since the stage 4 (stage main body 4b) is fixed to the chamber 2 (bottom plate 2b), the height position of the susceptor 4a is constant, and the height position of the substrate 3 can be changed by moving the lift pins 14 vertically.

The film-forming apparatus 1 includes a support base (adhesion preventing member support base) 18 capable of moving vertically (raising and lowering movement) and an adhesion preventing member (adhesion preventing plate) 19 attached to the support base 18 in the chamber 2. The support base 18 and the adhesion preventing member 19 attached to the support base 18 are disposed in the chamber 2 and are movable in the chamber 2. The adhesion preventing member 19 is provided for suppressing or preventing an unnecessary film from being formed (adhered) over the opening 11 of the chamber 2 and the opening and closing part 12 when a desired film is formed over the substrate 3. A shaft 20 is coupled to the support base 18.

Of the support base 18 and the adhesion preventing member 19, the support base 18 is located on the side closer to the side wall part 2c of the chamber 2, and the adhesion preventing member 19 is located on the side away from the side wall part 2c of the chamber 2. Namely, of the support base 18 and the adhesion preventing member 19, the adhesion preventing member 19 faces the space 7 and the stage 4, and the support base 18 faces the side wall part 2c of the chamber 2. As another embodiment, the support base 18 may be made smaller or omitted, and in this case, almost all of the combination of the support base 18 and the adhesion protection member 19 in FIG. 1 and FIG. 2 can be made as the adhesion preventing member 19.

The film-forming apparatus 1 further includes a driving mechanism (raising and lowering mechanism, operating mechanism, driving unit) 21 for raising and lowering the adhesion preventing member 19 (vertical movement, raising and lowering movement), and the shaft 20 is connected to the driving mechanism. 21. The driving mechanism. 21 is provided outside the chamber 2. By moving (raising and lowering) the shaft 20 vertically by the driving mechanism 21, the support base 18 coupled to the shaft 20 can be moved vertically (raised and lowered), so that the adhesion preventing member 19 attached to the support base 18 can be moved vertically (raised and lowered). Note that a part of the shaft 20 located outside the chamber 2 can pass through a bellows tube (not shown).

The film-forming apparatus 1 includes a control unit 22 that controls the driving mechanisms 17 and 21. The control unit 22 can be provided outside the chamber 2. The driving mechanisms 17 and 21 are controlled by the control unit 22, so that the vertical movement of the lift pins 14 and the vertical movement of the support base 18 and the adhesion preventing member 19 are controlled. For example, an air cylinder can be used as the driving mechanisms 17 and 21.

The support base 18 and the adhesion preventing member 19 attached thereto can move vertically between a lowered position (the position where the support base 18 and the adhesion preventing member 19 are lowered) and a raised position (the position where the support base 18 and the adhesion preventing member 19 are raised). In this embodiment, the adhesion preventing member 19 is not fixed to the chamber 2, and the height position of the adhesion preventing member 19 can be changed by moving the adhesion preventing member 19 vertically together with the support base 18.

When the support base 18 and the adhesion preventing member 19 are located at the lowered position, the support base 18 and the adhesion preventing member 19 are located at a position lower than the opening 11 of the chamber 2, and thus the support base 18 and the adhesion preventing member 19 are located at the position where they do not cover (not block, not overlap) the opening 11 of the chamber 2. When the substrate 3 is loaded into the chamber 2 through the opening 11 or the substrate 3 is unloaded to the outside of the chamber 2 through the opening 11, the support base 18 and the adhesion preventing member 19 are located at the lowered position. Therefore, it is possible to load the substrate 3 into the chamber 2 through the opening 11 and unload the substrate 3 to the outside of the chamber 2 through the opening 11 without being hindered by the support base 18 and the adhesion preventing member 19.

When the support base 18 and the adhesion preventing member 19 are located at the raised position, the adhesion preventing member 19 is located at almost the same height position as the opening 11 of the chamber 2, and thus the adhesion preventing member 19 is located at the position where it covers (blocks, overlaps) the opening 11 of the chamber 2. When the support base 18 and the adhesion preventing member 19 are located at the raised position, the substrate 3 cannot be transferred through the opening 11 because the support base 18 and the adhesion preventing member 19 get in the way. Therefore, when the support base 18 and the adhesion preventing member 19 are located at the raised position, the substrate 3 is not loaded into the chamber 2 through the opening 11 and the substrate 3 is not unloaded to the outside of the chamber 2 through the opening 11. When the film-forming step is performed to the substrate 3 placed over the stage 4 (susceptor 4a), the support base 18 and the adhesion preventing member 19 are located at the raised position. When the film-forming step is performed to the substrate 3, it is possible to suppress or prevent an unnecessary film from being formed over the opening 11 of the chamber 2 and the opening and closing part 12 by covering the opening 11 of the chamber 2 with the adhesion preventing member 19.

As another embodiment, it is also possible to adopt the configuration in which the adhesion preventing member 19 is located at the position where it covers the opening 11 of the chamber 2 when the support base 18 and the adhesion preventing member 19 are located at the lowered position and the adhesion preventing member 19 is located at the position where it does not cover the opening 11 of the chamber 2 when the support base 18 and the adhesion preventing member 19 are located at the raised position. In this case, the support base 18 and the adhesion preventing member 19 are located at the lowered position when the film-forming step is performed to the substrate 3, and the support base 18 and the adhesion preventing member 19 are located at the raised position when the substrate 3 is loaded into the chamber 2 or the substrate 3 is unloaded to the outside of the chamber 2. However, it is more preferable that the adhesion preventing member 19 is located at the position where it covers the opening 11 of the chamber 2 when the support base 18 and the adhesion preventing member 19 are located at the raised position as with this embodiment. In this manner, the dimensions (dimensions in a longitudinal direction) of the chamber 2 can be reduced more easily.

The adhesion preventing member 19 is attachable/detachable. Namely, the adhesion preventing member 19 can be easily detached from the support base 18, and the adhesion preventing member 19 can be easily attached to the support base 18. Therefore, at the time of maintenance or the like, the adhesion preventing member 19 can be detached from the support base 18, cleaned, and then attached again to the support base 18.

The support base 18 and the adhesion preventing member 19 can move vertically, and are configured to move along the side wall part 2c of the chamber 2. Specifically, since the opening 11 is provided in the side surface 10a of the chamber 2, the support base 18 and the adhesion preventing member 19 can move along the side surface 10a of the chamber 2. Since the support base 18 and the adhesion preventing member 19 move along the side wall part 2c (side surface 10a) of the chamber 2, the support base 18 and the adhesion preventing member 19 can be moved without being hindered by the upper electrode 5 and the stage 4, and it is possible to suppress or prevent the increase in size of the chamber 2 due to providing the support base 18 and the adhesion preventing member 19.

The film-forming apparatus 1 further includes adhesion preventing members 23, 24, 25, and 26 in addition to the adhesion preventing member 19 in the chamber 2. Among the adhesion preventing members 19, 23, 24, 25, and 26, only the adhesion preventing member 19 is configured to be movable in the chamber 2.

The adhesion preventing member (upper electrode adhesion preventing member, adhesion preventing plate) 23 is provided over a lower surface of the upper electrode 5 and covers the lower surface (main surface) and side surfaces of the upper electrode 5. Note that the lower surface of the upper electrode 5 is the main surface facing the stage 4 (susceptor 4a). The adhesion preventing member 23 is provided for suppressing or preventing an unnecessary film from being formed (adhered) over the lower surface and the side surfaces of the upper electrode 5 when a desired film is formed over the substrate 3.

The adhesion preventing member (adhesion preventing plate) 24 is supported by and fixed to the side wall part 2c (more specifically, the side surface 10b) of the chamber 2 with a support member 27 interposed therebetween. Namely, in the chamber 2, the adhesion preventing member 24 is disposed on the side closer to the side surface 10b of the chamber 2 and covers a part of the side surface 10b of the chamber 2.

The adhesion preventing member (adhesion preventing plate) 25 is supported by and fixed to the side wall part 2c (more specifically, the side surface 10c) of the chamber 2 with a support member 28 interposed therebetween. Namely, in the chamber 2, the adhesion preventing member 25 is disposed on the side closer to the side surface 10c of the chamber 2 and covers a part of the side surface 10c of the chamber 2.

The adhesion preventing member (adhesion preventing plate) 26 is supported by and fixed to the side wall part 2c (more specifically, the side surface 10d) of the chamber 2 with a support member 29 interposed therebetween. Namely, in the chamber 2, the adhesion preventing member 26 is disposed on the side closer to the side surface 10d of the chamber 2 and covers a part of the side surface 10d of the chamber 2. The adhesion preventing members 24, 25, and 26 are provided for suppressing or preventing an unnecessary film from being formed (adhered) over the side wall part 2c (side surfaces 10b, 10c, and 10d) of the chamber 2 when a desired film is formed over the substrate 3.

The adhesion preventing members 23, 24, 25, and 26 are attachable/detachable. Namely, the adhesion preventing member 23 can be easily detached from the upper electrode 5, and the adhesion preventing member 23 can be easily attached to the upper electrode 5. In addition, the adhesion preventing members 24, 25, and 26 can be easily detached from the side wall part 2c of the chamber 2, and the adhesion preventing members 24, 25, and 26 can be easily attached to the side wall part 2c of the chamber 2. Therefore, at the time of maintenance or the like, the adhesion preventing members 23, 24, 25, and 26 can be detached, cleaned, and then attached again.

In the chamber 2, the adhesion preventing member 24 is disposed at the position on an opposite side to the opening 11. Therefore, when the support base 18 and the adhesion preventing member 19 are located at the raised position and the adhesion preventing member 19 is located at the position where it covers (blocks) the opening 11 of the chamber 2, the adhesion preventing member 19 and the adhesion preventing member 24 are located at the positions opposite to each other in the chamber 2. The adhesion preventing member 24 and the adhesion preventing member 19 located at the position where it covers the opening 11 face each other with the susceptor 4a and the upper electrode 5 interposed therebetween. Also, the adhesion preventing member 25 and the adhesion preventing member 26 face each other with the susceptor 4a and the upper electrode 5 interposed therebetween.

When the film-forming step is performed to the substrate 3, the adhesion preventing member 19 is located at the raised position, and thus the adhesion preventing member 19 and the adhesion preventing member 24 are disposed so as to face each other with the susceptor 4a and the upper electrode 5 interposed therebetween. Namely, the adhesion preventing member 19 and the adhesion preventing member 24 are disposed at symmetrical positions with the susceptor 4a and the upper electrode 5 interposed therebetween. Accordingly, it is possible to prevent the uneven flow of the source gas and the reaction gas introduced into the chamber 2 through the gas introduction part 8, and it is thus possible to easily and accurately form a uniform film over the substrate 3.

In plan view, the adhesion preventing members 19, 24, 25, and 26 surround the upper electrode 5 (adhesion preventing member 23), the space 7, and the susceptor 4a. When the adhesion preventing member 19 is located at the raised position, each of the adhesion preventing members 19, 24, 25, and 26 faces the susceptor 4a, the adhesion preventing member 23, and the space 7. Therefore, when the adhesion preventing member 19 is located at the raised position, the space 7 is surrounded by the upper electrode 5 (adhesion preventing member 23), the susceptor 4a, and the adhesion preventing members 19, 24, 25, and 26. However, the adhesion preventing member 25 does not block the gas introduction part 8, and the adhesion preventing member 26 does not block the gas exhaust part 9. Therefore, the space 7 and the gas introduction part 8 are continuously (spatially) connected and the space 7 and the gas exhaust part 9 are continuously (spatially) connected without being blocked by the adhesion preventing members 19, 24, 25, and 26. Meanwhile, when the adhesion preventing member 19 is located at the raised position, the adhesion preventing member 19 is disposed between the space 7 and the opening 11, and the space 7 and the opening 11 are separated by the adhesion preventing member 19. Note that “in plan view” means the case of being seen on a plane parallel to the upper surface of the susceptor 4a or the lower surface of the upper electrode 5.

It is preferable that the support base 18 and the adhesion preventing member 19 are configured so as not to be in contact with the side wall part 2c of the chamber 2, the stage 4, and the adhesion preventing member 23 when they are moved vertically. In this manner, it is possible to prevent the support base 18 or the adhesion preventing member 19 from being rubbed with other members and prevent occurrence of foreign matters when the support base 18 and the adhesion preventing member 19 are moved vertically. However, if the support base 18 and the adhesion preventing member 19 are excessively separated from the side wall part 2c of the chamber 2, the stage 4, and the adhesion preventing member 23, there is a concern that the source gas and the reaction gas may be diffused from the gaps thereof to form an unnecessary film and the chamber 2 may be increased in size. From this viewpoint, the gap between the combination of the support base 18 and the adhesion preventing member 19 and the side wall part 2c of the chamber 2 (here, the interval between the support base 18 and the side surface 10a) is preferably 0.5 to 10 mm, and is most preferably about 2 mm. Also, the gap between the combination of the support base 18 and the adhesion preventing member 19 and the stage 4 (here, the interval between the adhesion preventing member 19 and the stage 4) is preferably 0.5 to 10 mm, and is most preferably about 2 mm. Further, when the support base 18 and the adhesion preventing member 19 are located at the raised position, the gap between the combination of the support base 18 and the adhesion preventing member 19 and the adhesion preventing member 23 (here, the interval between the adhesion preventing member 19 and the adhesion preventing member 23) is preferably 0.5 to 10 mm, and is most preferably about 2 mm.

In addition, the interval between each of the adhesion preventing members 24, 25, and 26 and the stage 4 (susceptor 4a) is preferably 0.5 to 10 mm, and is most preferably about 2 mm. Further, the interval between each of the adhesion preventing members 24, 25, and 26 and the adhesion preventing member 23 is preferably 0.5 to 10 mm, and is most preferably about 2 mm. In this manner, it is possible to easily suppress or prevent the formation of an unnecessary film by suppressing the source gas and the reaction gas from being diffused through the gaps between the adhesion preventing members 24, 25, and 26 and the stage 4 (susceptor 4a) and the gaps between the adhesion preventing members 24, 25, and 26 and the adhesion preventing member 23, and it is also possible to prevent the increase in size of the chamber 2. Further, it becomes easy to manufacture (assemble) the film-forming apparatus 1.

In addition, the chamber 2 is provided with an inert gas introduction part (inert gas supply part, inert gas supply port, opening) 31 for introducing (supplying) inert gas into the chamber 2. As described above, the inert gas introduction part 31 for introducing inert gas is separately provided in the film-forming apparatus 1 in addition to the gas introduction part 8 for introducing source gas, purge gas, and reaction gas. As the inert gas introduced into the chamber 2 through the inert gas introduction part 31, nitrogen gas may be used. The inert gas introduction part 31 is provided in the side wall part 2c of the chamber 2.

The inert gas introduction part 31 includes inert gas introduction parts 31a and 31b for supplying inert gas to the surface of the adhesion preventing member 19, inert gas introduction parts 31c and 31d for supplying inert gas to the surface of the adhesion preventing member 24, inert gas introduction parts 31e and 31f for supplying inert gas to the surface of the adhesion preventing member 25, and inert gas introduction parts 31g and 31h for supplying inert gas to the surface of the adhesion preventing member 26.

The inert gas introduction parts 31a and 31b are provided in the side surface 10a of the chamber 2 and are disposed so as to be located near the adhesion preventing member 19 when the adhesion preventing member 19 is located at the raised position. Therefore, the inert gas introduction parts 31a and 31b are disposed near the opening 11. This is because, when introducing the inert gas into the chamber 2 through the inert gas introduction part 31 (that is, when performing the step S2 described later), the adhesion preventing member 19 is located at the raised position and the adhesion preventing member 19 at the raised position covers the opening 11. Of the inert gas introduction parts 31a and 31b, the inert gas introduction part 31a is disposed at a higher position (upper side) than the opening 11, and the inert gas introduction part 31b is disposed at a lower position (lower side) than the opening 11. In a state where the adhesion preventing member 19 covers the opening 11, the inert gas can be supplied to the surface of the adhesion preventing member 19 through the inert gas introduction parts 31a and 31b.

The inert gas introduction parts 31c and 31d are provided in the side surface 10b of the chamber 2 and are disposed near the adhesion preventing member 24. Of the inert gas introduction parts 31c and 31d, the inert gas introduction part 31c is disposed at a higher position (upper side) than the inert gas introduction part 31d. The inert gas can be supplied to the surface of the adhesion preventing member 24 through the inert gas introduction parts 31c and 31d.

The inert gas introduction parts 31e and 31f are provided in the side surface 10c of the chamber 2 and are disposed near the adhesion preventing member 25. Of the inert gas introduction parts 31e and 31f, the inert gas introduction part 31e is disposed at a higher position (upper side) than the inert gas introduction part 31f. The inert gas can be supplied to the surface of the adhesion preventing member 25 through the inert gas introduction parts 31e and 31f.

The inert gas introduction parts 31g and 31h are provided in the side surface 10d of the chamber 2 and are disposed near the adhesion preventing member 26. Of the inert gas introduction parts 31g and 31h, the inert gas introduction part 31g is disposed at a higher position (upper side) than the inert gas introduction part 31h. The inert gas can be supplied to the surface of the adhesion preventing member 26 through the inert gas introduction parts 31g and 31h.

The inert gas introduction parts 31a and 31b are formed in the side surface 10a of the chamber 2, the inert gas introduction parts 31c and 31d are formed in the side surface 10b of the chamber 2, the inert gas introduction parts 31e and 31f are formed in the side surface 10c of the chamber 2, and the inert gas introduction parts 31g and 31h are formed in the side surface 10d of the chamber 2. The height position of the inert gas introduction part 31a, the height position of the inert gas introduction part 31c, the height position of the inert gas introduction part 31e, and the height position of the inert gas introduction part 31g are almost the same. Also, the height position of the inert gas introduction part 31b, the height position of the inert gas introduction part 31d, the height position of the inert gas introduction part 31f, and the height position of the inert gas introduction part 31h are almost the same. Therefore, in the chamber 2, the inert gas introduction part 31c is disposed at the position facing the inert gas introduction part 31a, the inert gas introduction part 31d is disposed at the position facing the inert gas introduction part 31b, the inert gas introduction part 31g is disposed at the position facing the inert gas introduction part 31e, and the inert gas introduction part 31h is disposed at the position facing the inert gas introduction part 31f.

As can be seen from FIG. 5, a plurality of inert gas introduction parts 31b are provided in the side surface 10a of the chamber 2, and for example, the plurality of inert gas introduction parts 31b are arranged in the Y direction at predetermined intervals. In addition, a plurality of inert gas introduction parts 31a are also provided in the side surface 10a of the chamber 2 as with the inert gas introduction part 31b shown in FIG. 5, and for example, the plurality of inert gas introduction parts 31a are arranged in the Y direction at predetermined intervals. Therefore, in the side wall part 2c of the chamber 2 forming the side surface 10a, a plurality of inert gas introduction parts 31 (31a, 31b) are formed above and below the opening 11, that is, are formed on each of the upper side and the lower side of the opening 11.

Also, as can be seen from FIG. 5, a plurality of inert gas introduction parts 31d are provided in the side surface 10b of the chamber 2, and for example, the plurality of inert gas introduction parts 31d are arranged in the Y direction at predetermined intervals. In addition, a plurality of inert gas introduction parts 31c are also provided in the side surface 10b of the chamber 2 as with the inert gas introduction part 31d shown in FIG. 5, and for example, the plurality of inert gas introduction parts 31c are arranged in the Y direction at predetermined intervals.

Also, as can be seen from FIG. 5, a plurality of inert gas introduction parts 31f are provided in the side surface 10c of the chamber 2, and for example, the plurality of inert gas introduction parts 31f are arranged in the X direction at predetermined intervals. In addition, a plurality of inert gas introduction parts 31e are also provided in the side surface 10c of the chamber 2 as with the inert gas introduction part 31f shown in FIG. 5, and for example, the plurality of inert gas introduction parts 31e are arranged in the X direction at predetermined intervals.

Also, as can be seen from FIG. 5, a plurality of inert gas introduction parts 31h are provided in the side surface 10d of the chamber 2, and for example, the plurality of inert gas introduction parts 31h are arranged in the X direction at predetermined intervals. In addition, a plurality of inert gas introduction parts 31g are also provided in the side surface 10d of the chamber 2 as with the inert gas introduction part 31h shown in FIG. 5, and for example, the plurality of inert gas introduction parts 31g are arranged in the X direction at predetermined intervals. The inert gas introduction parts 31a, 31b, 31c, 31d, 31e, 31f, 31g, and 31h can have a shower-head structure.

### Film-Forming Process

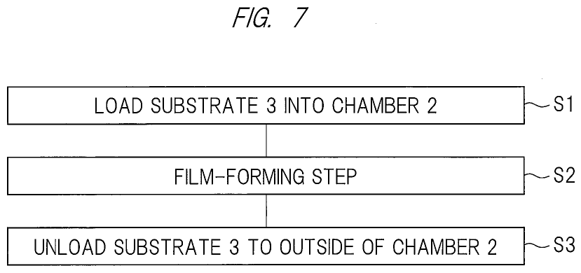

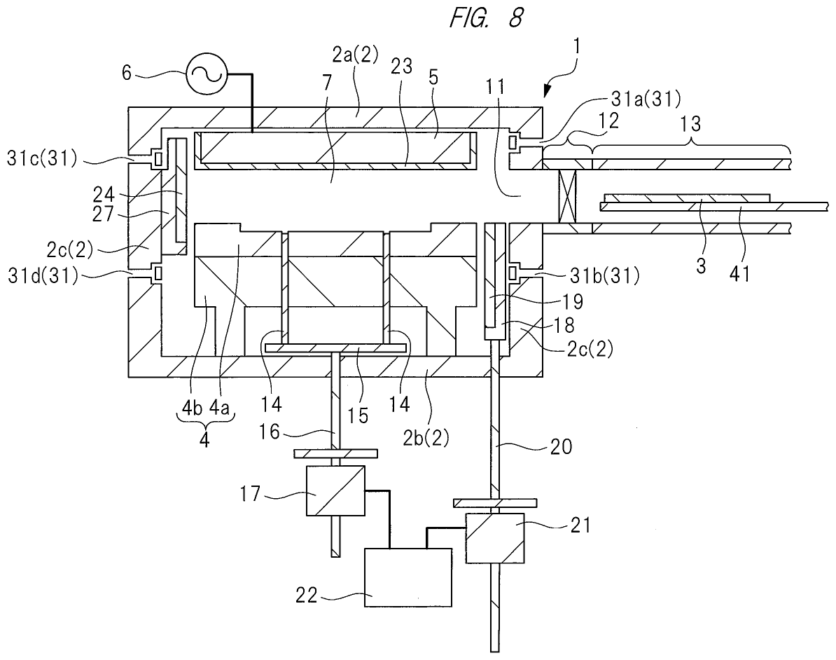

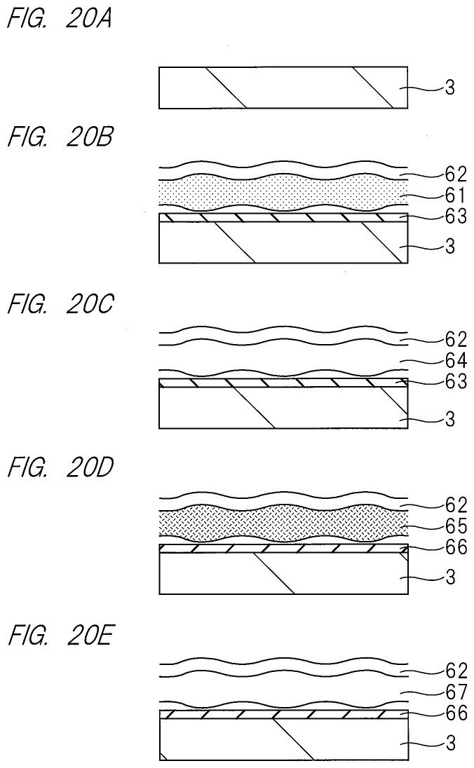

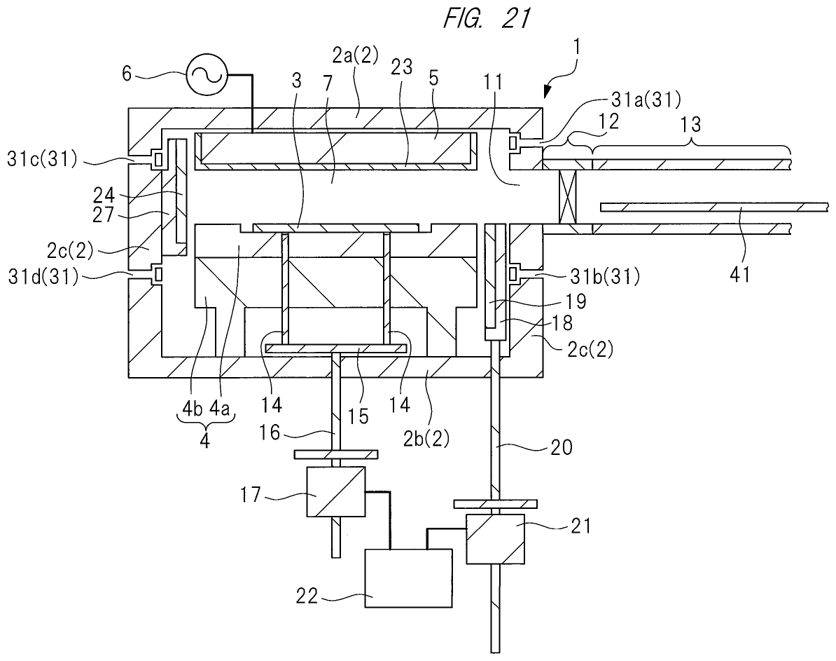

The film-forming process using the film-forming apparatus 1 (film-forming process by ALD method) will be described with reference to FIG. 7 to FIG. 26. FIG. 7 is a process flowchart showing a film-forming process using the film-forming apparatus 1. FIG. 8 to FIG. 19 and FIG. 21 to FIG. 26 are explanatory diagrams (cross-sectional views) showing the film-forming process using the film-forming apparatus 1. Among them, FIG. 8 to FIG. 14 and FIG. 21 to FIG. 26 show the cross section corresponding to FIG. 2, and FIG. 15 to FIG. 19 show the cross section corresponding to FIG. 3. FIG. 20A to FIG. 20E are explanatory diagrams of a film-forming step (step S2) in the film-forming process.

The film-forming process using the film-forming apparatus 1 can be performed as follows.

First, the substrate 3 which is an object to perform the film-forming step is loaded into the chamber 2 of the film-forming apparatus 1 (step S1 of FIG. 7). Specifically, this step S1 (substrate loading step) can be performed as follows.

First, as shown in FIG. 8, the substrate 3 is placed or held over a substrate transfer robot arm (substrate transfer hand) 41, and is transferred to the substrate transfer path 13 from a transfer chamber or the like. Thus, the substrate 3 disposed (held) over the robot arm 41 is in a stand-by state in the substrate transfer path 13. At this stage, the opening and closing part 12 is in the closed state. Further, the lift pins 14 are at the lowered position, and the support base 18 and the adhesion preventing member 19 are also at the lowered position.

Next, the opening and closing part 12 is opened. Consequently, the opening and closing part 12 is switched from the closed state to the open state, so that the space in the chamber 2 and the space of the substrate transfer path 13 are continuously (spatially) connected via the opening 11 and the opening and closing part 12 in the open state.

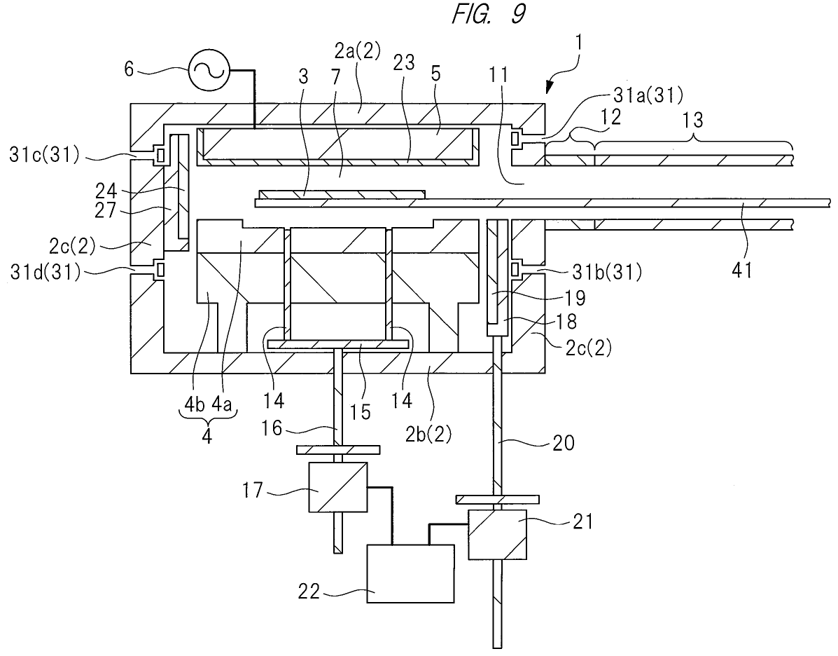

Next, as shown in FIG. 9, by operating the robot arm 41, the substrate 3 disposed (held) over the robot arm 41 is loaded into the chamber through the opening 11. Since the opening and closing part 12 is in the open state, the robot arm 41 and the substrate 3 can enter the chamber 2 through the opening and closing part 12 and the opening 11. The substrate 3 moves in a horizontal direction by the robot arm 41 and reaches the position above the stage 4 (more specifically, the position above the susceptor 4a). Since the support base 18 and the adhesion preventing member 19 are at the lowered position, an upper end of the adhesion preventing member 19 and an upper end of the support base 18 are lower than a lower end of the opening 11 of the chamber 2, and it is possible to load the substrate 3 into the chamber 2 through the opening 11 without being hindered by the adhesion preventing member 19 and the support base 18. At this stage, the lift pins 14 are at the lowered position, and the lift pins 14 do not protrude from the upper surface of the susceptor 4a. Also, since at least a part of the opening 11 of the chamber 2 is located at the same height position as the space 7 between the stage 4 (susceptor 4a) and the upper electrode 5, the robot arm 41 and the substrate 3 loaded into the chamber 2 through the opening 11 can be easily disposed in the space 7 between the stage 4 (susceptor 4a) and the upper electrode 5.

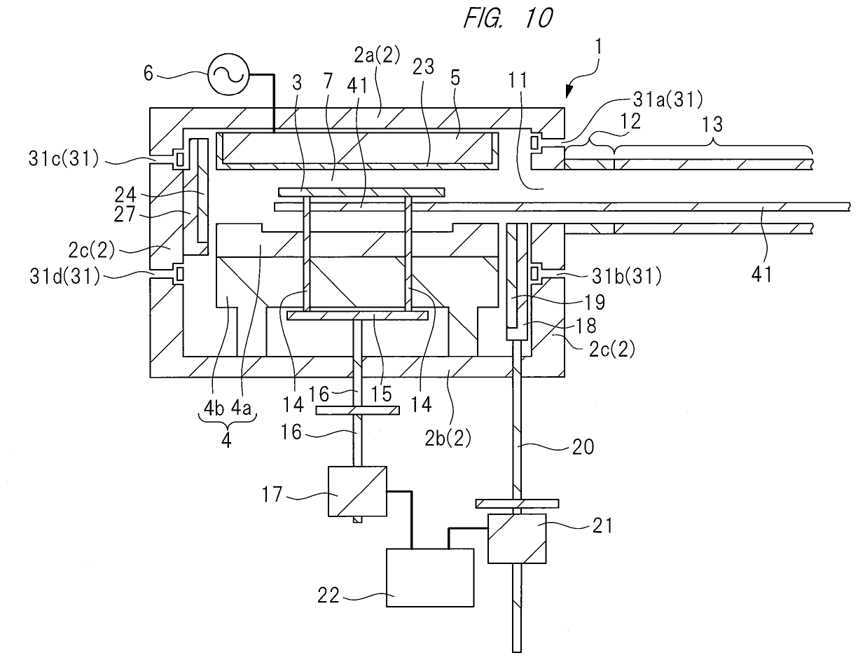

Next, as shown in FIG. 10, the driving mechanism 17 is controlled by the control unit 22 and the shaft 16 is raised by the driving mechanism 17, so that the support member 15 coupled to the shaft 16 is raised and the lift pins 14 coupled to the support member 15 are raised. Namely, the lift pins 14 are moved from the lowered position to the raised position. Consequently, the lift pins 14 protrude from the upper surface of the susceptor 4a, and the lift pins 14 contact the lower surface of the substrate 3 disposed (held) over the robot arm 41 and lift up (push up) the substrate 3. The substrate 3 is supported by the lift pins 14 and is separated (floated) from the robot arm 41.

Next, as shown in FIG. 11, the robot arm 41 returns to the substrate transfer path 13 outside the chamber 2. Namely, the robot arm 41 moves to the outside of the chamber 2 through the opening 11 and the opening and closing part 12 in the open state. Since the substrate 3 is supported by the lift pins 14, even when the robot arm 41 returns to the substrate transfer path 13, the substrate 3 keeps the state of being supported by the lift pins 14 in the chamber 2.

Next, the opening and closing part 12 is closed. Thus, the opening and closing part 12 is switched from the open state to the closed state, so that the space in the chamber 2 and the space of the substrate transfer path 13 are separated by the opening and closing part 12 in the closed state.

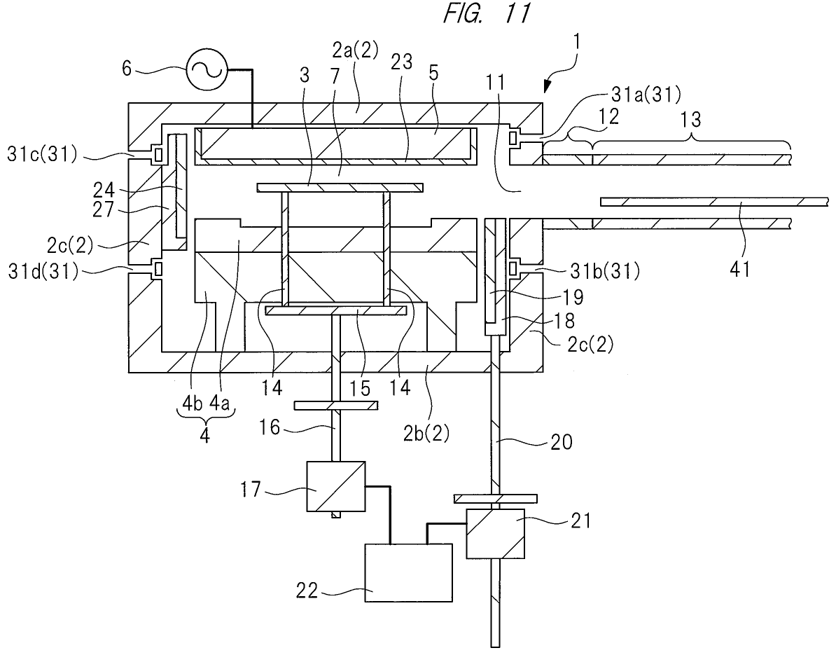

Next, as shown in FIG. 12, the driving mechanism 17 is controlled by the control unit 22 and the shaft 16 is lowered by the driving mechanism 17, so that the support member 15 coupled to the shaft 16 is lowered and the lift pins 14 coupled to the support member 15 are lowered. Namely, the lift pins 14 are moved from the raised position to the lowered position. Consequently, the substrate 3 supported by the lift pins 14 is also lowered together with the lift pins 14. When the lift pins 14 are lowered, the tops (upper surfaces) of the lift pins 14 are lower than the upper surface of the susceptor 4a, and the lift pins 14 do not protrude from the upper surface of the susceptor 4a. Accordingly, the substrate 3 lowered together with the lift pins 14 contacts the upper surface of the susceptor 4a, and afterward, the tops (upper surfaces) of the lift pins 14 are separated from the substrate 3 and the substrate 3 is supported by the susceptor 4a instead of the lift pins 14. Namely, the substrate 3 is in contact with the upper surface of the susceptor 4a and is placed over the susceptor 4a.

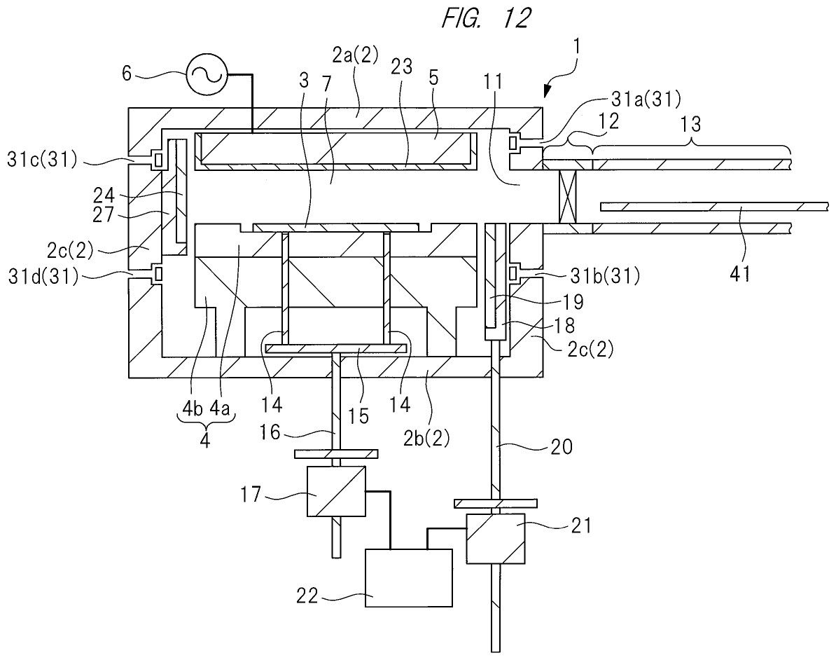

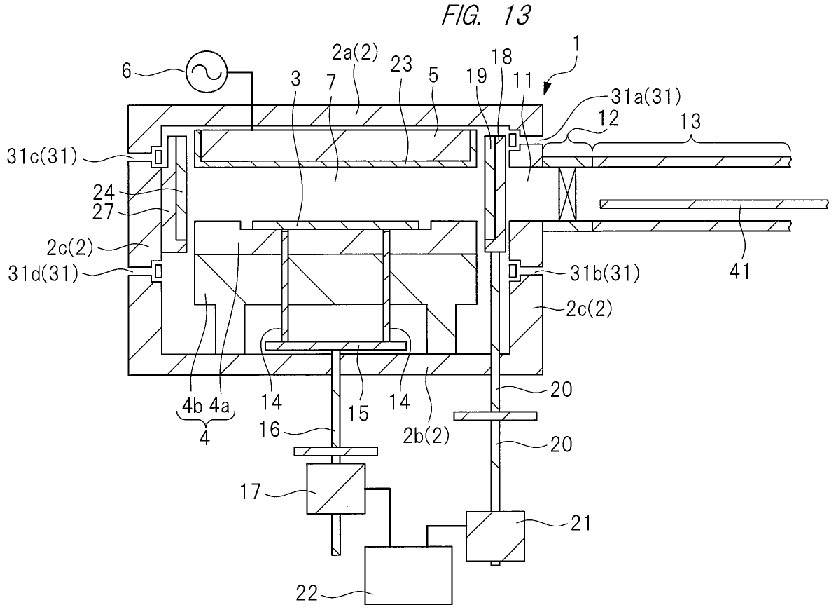

Next, as shown in FIG. 13, the driving mechanism 21 is controlled by the control unit 22 and the shaft 20 is raised by the driving mechanism 21, so that the support base 18 coupled to the shaft 20 is raised. Consequently, the adhesion preventing member 19 attached to the support base 18 is also raised together with the support base 18. Namely, the support base 18 and the adhesion preventing member 19 are moved from the lowered position to the raised position. Consequently, the adhesion preventing member 19 is located at almost the same height position as the opening 11 of the chamber 2, and thus the adhesion preventing member 19 is located at the position where it covers (blocks) the opening 11 of the chamber 2.

In this manner, the step S1 (substrate loading step) can be performed. By performing the step S1, the substrate 3 is loaded into the chamber 2, and the substrate 3 is placed over the stage 4 (susceptor 4a) in the chamber 2.

In the step S1, the process of closing the opening and closing part 12 (FIG. 12), the process of moving the lift pins 14 from the raised position to the lowered position (FIG. 12), and the process of moving the adhesion preventing member 19 from the lowered position to the raised position (FIG. 13) are preferably performed in this order, but as another embodiment, the order thereof may be changed. However, the process of closing the opening and closing part 12 (FIG. 12), the process of moving the lift pins 14 from the raised position to the lowered position (FIG. 12), and the process of moving the adhesion preventing member 19 from the lowered position to the raised position (FIG. 13) need to be performed after the robot arm 41 is returned to the substrate transfer path 13 as shown in FIG. 11 and before the step S2 described later is performed.

Next, the film-forming step is performed to the substrate 3 placed over the stage 4 (susceptor 4a) in the chamber 2 (step S2 of FIG. 7). Specifically, this step S2 (film-forming step) can be performed as follows.

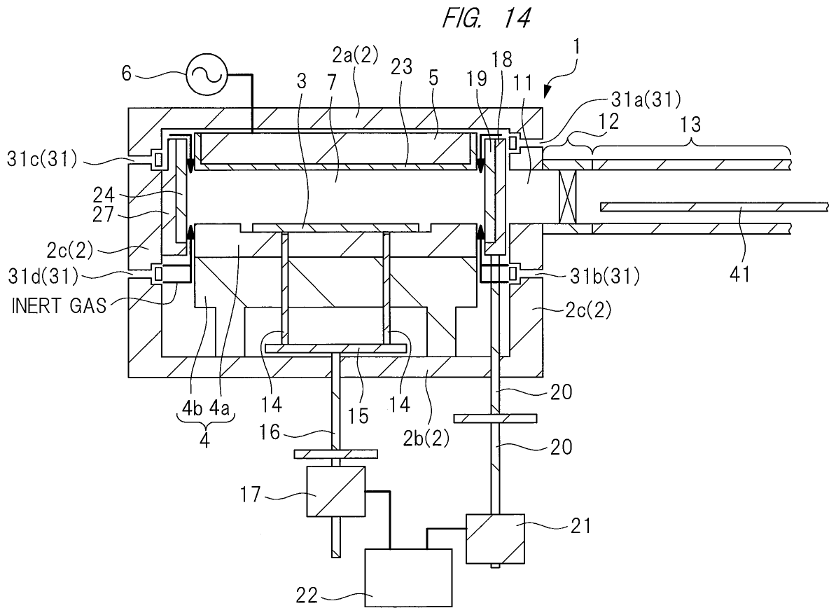

First, as shown in FIG. 14 and FIG. 15, the inert gas is introduced (supplied) into the chamber 2 through the inert gas introduction part 31 (31a, 31b, 31c, 31d, 31e, 31f, 31g, and 31h). As the inert gas introduced into the chamber 2 through the inert gas introduction part 31, nitrogen gas may be used in some cases. As described above, the inert gas introduction part 31 includes the inert gas introduction parts 31a, 31b, 31c, 31d, 31e, 31f, 31g, and 31h. Note that, in FIG. 14 and FIG. 15, the flow of the inert gas introduced into the chamber 2 through the inert gas introduction part 31 (31a, 31b, 31c, 31d, 31e, 31f, 31g, and 31h) is schematically shown by arrows. The inert gas introduced into the chamber 2 through the inert gas introduction part 31 is exhausted through the gas exhaust part 9. The introduction of the inert gas into the chamber 2 through the inert gas introduction part 31 is continued also in the first step, the second step, the third step, and the fourth step described later.

Next, by repeating the first step, the second step, the third step, and the fourth step described later in plural cycles, a desired film (for example, aluminum oxide film) with a desired thickness can be formed over the surface of the substrate 3. This will be described in detail below.

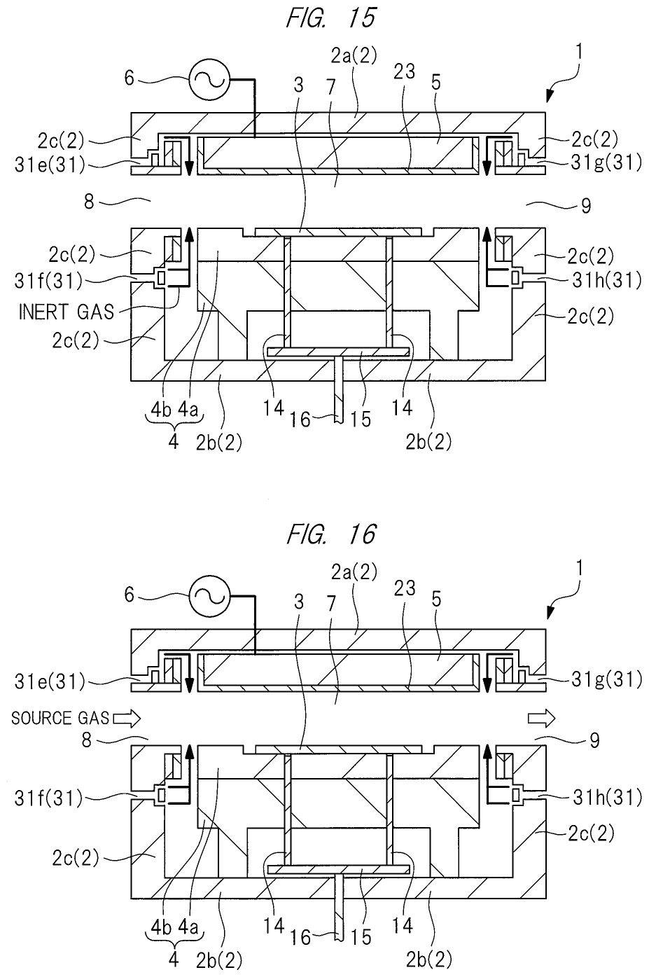

First, as the first step (source gas supply step), the source gas is introduced (supplied) into the chamber 2 through the gas introduction part 8 as shown in FIG. 16. When an aluminum oxide film is to be formed, for example, TMA (Trimethylaluminum) gas can be used as the source gas. The source gas introduced into the chamber 2 through the gas introduction part 8 mainly passes through the space 7 between the upper electrode 5 and the stage 4 (susceptor 4a) and is exhausted through the gas exhaust part 9. By performing the first step, molecules of the source gas are adsorbed to the surface of the substrate 3 placed over the stage 4 (susceptor 4a). Namely, an adsorption layer of the source gas is formed over the surface of the substrate 3 (see FIG. 20B).

Note that FIG. 20A shows the substrate 3 loaded into the chamber 2 and placed over the stage 4 in the step S1. Also, FIG. 20B shows the state where source gas 61 (source gas supplied through the gas introduction part 8) and inert gas 62 (inert gas supplied through the inert gas introduction part 31) are supplied to the space above the substrate 3 and an adsorption layer 63 of the source gas is formed over the surface of the substrate 3 by performing the first step.

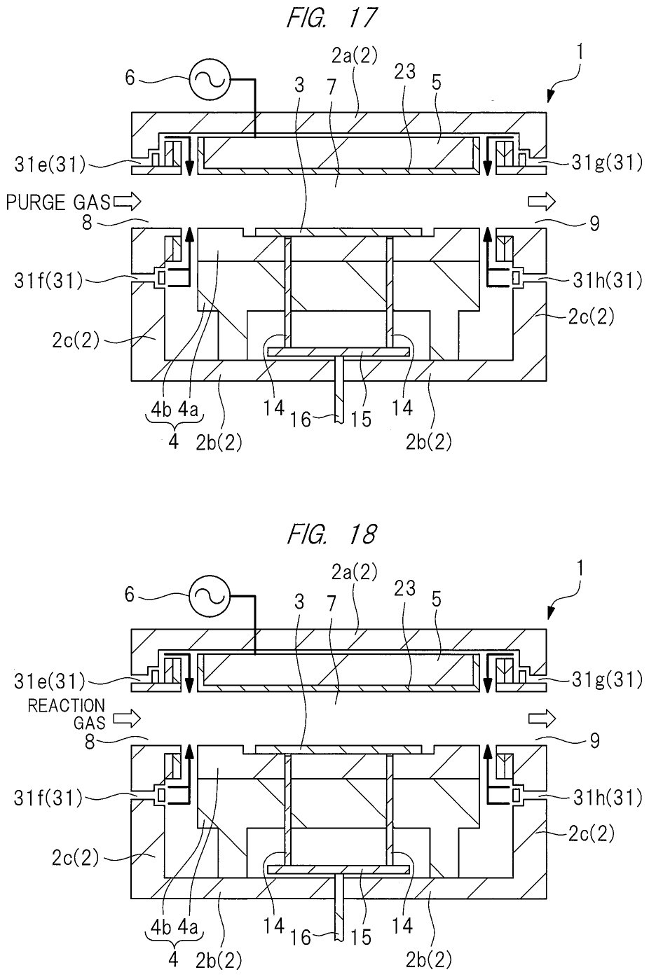

Next, as the second step (purge step), the introduction of the source gas into the chamber 2 is stopped, and purge gas is introduced into the chamber 2 through the gas introduction part 8 as shown in FIG. 17. As the purge gas, inert gas can be suitably used, and nitrogen gas (N₂ gas) may be used in some cases. By introducing the purge gas, the molecules of the source gas adsorbed to the surface of the substrate 3 (adsorption layer of the source gas) are left, but the source gas other than that (source gas not adsorbed to the substrate 3) is exhausted (purged) to the outside of the chamber 2 together with the purge gas. The purge gas introduced into the chamber 2 through the gas introduction part 8 mainly passes through the space 7 between the upper electrode 5 and the stage (susceptor 4a) and is exhausted through the gas exhaust part 9.

Note that FIG. 20C shows the state where purge gas 64 (purge gas supplied through the gas introduction part 8) and the inert gas 62 (inert gas supplied through the inert gas introduction part 31) are supplied to the space above the substrate 3 and the adsorption layer 63 over the surface of the substrate 3 is left by performing the second step.

Next, as the third step (reaction gas supply step), reaction gas is introduced (supplied) into the chamber 2 through the gas introduction part 8 as shown in FIG. 18. When an aluminum oxide film is to be formed, for example, O₂ gas (oxygen gas) can be used as the reaction gas. The reaction gas introduced into the chamber 2 through the gas introduction part 8 mainly passes through the space 7 between the upper electrode 5 and the stage 4 (susceptor 4a) and is exhausted through the gas exhaust part 9. Then, the high frequency power supply 6 applies a high frequency power to the upper electrode 5, that is, between the upper electrode 5 and the stage (more specifically, the susceptor 4a). Consequently, plasma discharge is generated between the upper electrode 5 and the stage 4 (susceptor 4a) and the reaction gas (here, O₂ gas) in the space 7 is converted into plasma, so that radicals (active species) are generated in the reaction gas and molecules of the source gas (adsorption layer of the source gas) adsorbed to the surface of the substrate 3 react with the reaction gas. In this manner, an atomic layer (single layer) of aluminum oxide which is a reaction layer between the adsorption layer of the source gas and the reaction gas (plasma of the reaction gas) is formed over the surface of the substrate 3.

Note that FIG. 20D shows the state where reaction gas 65 (reaction gas supplied through the gas introduction part 8) and the inert gas 62 (inert gas supplied through the inert gas introduction part 31) are supplied to the space above the substrate 3 and an atomic layer 66 which is a reaction layer between the adsorption layer 63 and the reaction gas is formed over the surface of the substrate 3 by performing the third step.

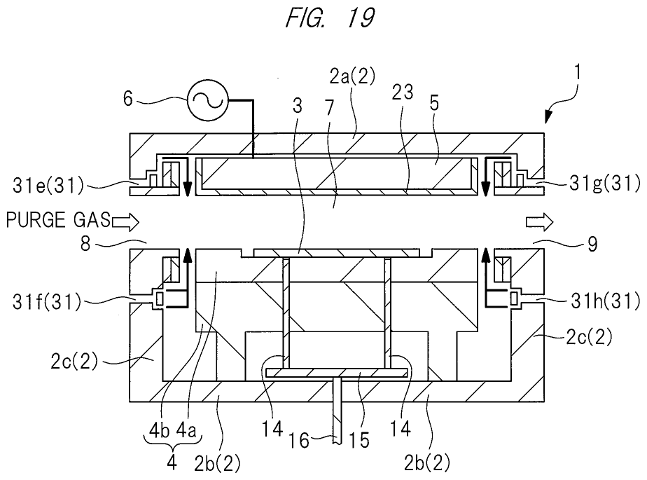

Next, as the fourth step (purge step), the introduction of the reaction gas into the chamber 2 and the application of the high frequency power to the upper electrode 5 are stopped and purge gas is introduced (supplied) into the chamber 2 through the gas introduction part 8 as shown in FIG. 19. As the purge gas, inert gas can be suitably used, and nitrogen gas (N₂ gas) may be used in some cases. By introducing the purge gas, the reaction gas is exhausted (purged) to the outside of the chamber 2 through the gas exhaust part 9 together with the purge gas. The purge gas introduced into the chamber 2 through the gas introduction part 8 mainly passes through the space 7 between the upper electrode 5 and the stage (susceptor 4a) and is exhausted through the gas exhaust part 9.

Note that FIG. 20D shows the state where purge gas 67 (purge gas supplied through the gas introduction part 8) and the inert gas 62 (inert gas supplied through the inert gas introduction part 31) are supplied to the space above the substrate 3 and the atomic layer 66 over the surface of the substrate 3 is left by performing the fourth step.

By repeating the first step, the second step, the third step, and the fourth step described above in plural cycles, a desired film (for example, aluminum oxide film) with a desired thickness can be formed over the surface of the substrate 3. For example, by repeating the first step, the second step, the third step, and the fourth step described above in thirty cycles, a film made up of thirty atomic layers is formed, and by repeating the first step, the second step, the third step, and the fourth step described above in sixty cycles, a film made up of sixty atomic layers is formed.

After a desired film is formed over the surface of the substrate 3 by repeating the first step, the second step, the third step, and the fourth step in plural cycles, the introduction of the inert gas into the chamber 2 through the inert gas introduction part 31 is stopped. Note that, when the step S2 (film-forming step) is being performed, the support base 18 and the adhesion preventing member 19 are located at the raised position, the lift pins 14 are located at the lowered position, and the opening and closing part 12 is in the closed state.

After a desired film is formed over the substrate 3 by performing the film-forming step of the step S2 in the manner described above, the substrate 3 is unloaded from the chamber 2 of the film-forming apparatus 1 to the outside of the chamber 2 (step S7 of FIG. 7). Specifically, this step S3 (substrate unloading step) can be performed as follows.

First, as shown in FIG. 21, the driving mechanism 21 is controlled by the control unit 22 and the shaft 20 is lowered by the driving mechanism 21, so that the support base 18 coupled to the shaft 20 is lowered. Consequently, the adhesion preventing member 19 attached to the support base 18 is also lowered together with the support base 18. Namely, the support base 18 and the adhesion preventing member 19 are moved from the raised position to the lowered position. Consequently, the support base 18 and the adhesion preventing member 19 are located at the position lower than the opening 11 of the chamber 2, and thus the support base 18 and the adhesion preventing member 19 are located at the position where they do not cover (not block) the opening 11 of the chamber 2.

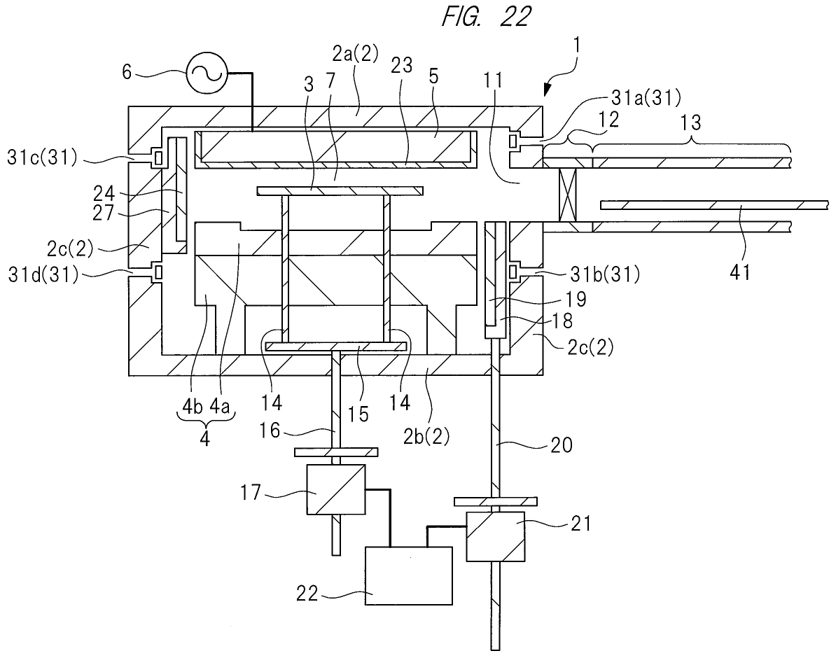

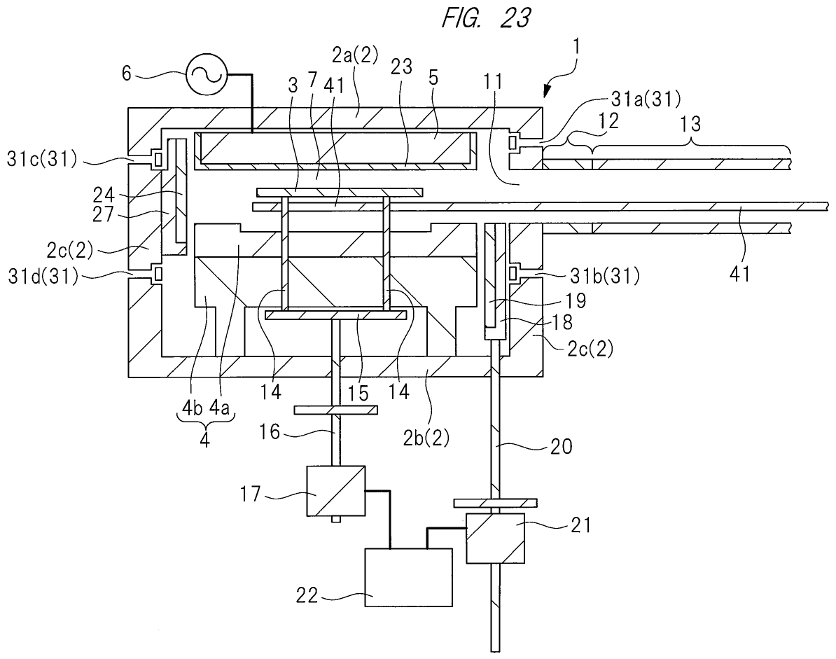

Next, as shown in FIG. 22, the driving mechanism 17 is controlled by the control unit 22 and the shaft 16 is raised by the driving mechanism 17, so that the support member 15 coupled to the shaft 16 is raised and the lift pins 14 coupled to the support member 15 are raised. Namely, the lift pins 14 are moved from the lowered position to the raised position. Consequently, the lift pins 14 protrude from the upper surface of the susceptor 4a, and the lift pins 14 contact the lower surface of the substrate 3 placed over the susceptor 4a and lift up (pushup) the substrate 3. The substrate 3 is supported by the lift pins 14, is moved to the position higher than the upper surface of the susceptor 4a, and is separated (floated) from the susceptor 4a.

Next, the opening and closing part 12 is opened. Consequently, the opening and closing part 12 is switched from the closed state to the open state, so that the space in the chamber 2 and the space of the substrate transfer path 13 are continuously (spatially) connected via the opening 11 and the opening and closing part 12 in the open state.

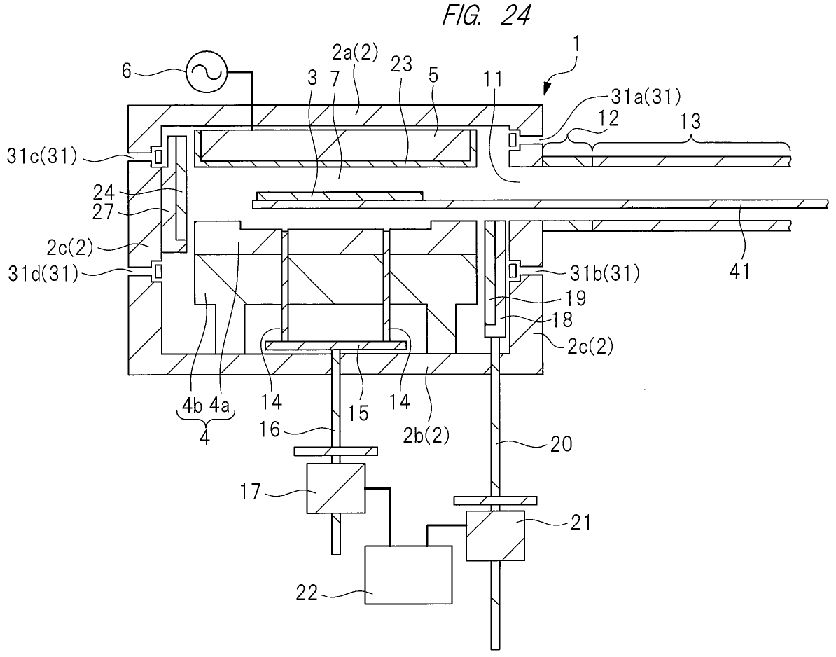

Next, as shown in FIG. 23, the robot arm 41 is operated to enter the chamber 2 through the opening 11. Since the opening and closing part 12 is in the open state, the robot arm 41 can enter the chamber 2 through the opening and closing part 12 and the opening 11. The robot arm 41 moves in a horizontal direction so as to be located below the substrate 3 lifted by the lift pins 14. At this stage, the substrate 3 is supported by the lift pins 14 and is located at the position higher than the robot arm 41. Therefore, although the robot arm 41 is located below the substrate 3, the substrate 3 is separated from the robot arm 41. Since the support base 18 and the adhesion preventing member 19 are at the lowered position, the upper end of the adhesion preventing member 19 and the upper end of the support base 18 are lower than the lower end of the opening 11 of the chamber 2, and the robot arm 41 can enter the chamber 2 through the opening 11 without being hindered by the adhesion preventing member 19 and the support base 18.

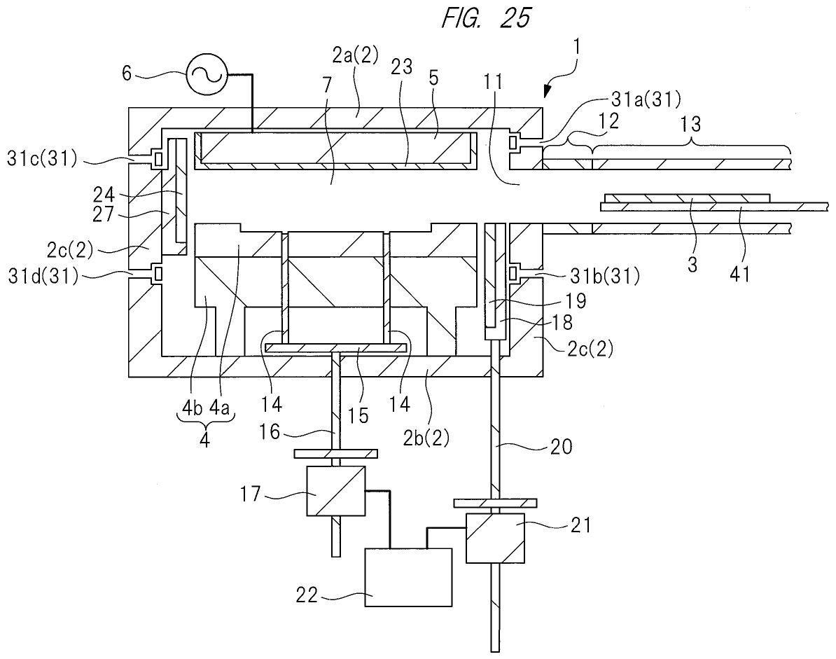

Next, as shown in FIG. 24, the driving mechanism 17 is controlled by the control unit 22 and the shaft 16 is lowered by the driving mechanism 17, so that the support member 15 coupled to the shaft 16 is lowered and the lift pins 14 coupled to the support member 15 are lowered. Namely, the lift pins 14 are moved from the raised position to the lowered position. Consequently, the substrate 3 supported by the lift pins 14 is also lowered together with the lift pins 14, but after the lower surface of the substrate 3 contacts the robot arm 41, the substrate 3 is supported by the robot arm 41 instead of the lift pins 14. Then, the tops (upper surfaces) of the lift pins 14 are separated from the substrate 3 and become lower than the upper surface of the susceptor 4. Namely, the lift pins 14 do not protrude from the upper surface of the susceptor 4a. The substrate 3 is in contact with the upper surface of the robot arm 41 and is placed over the robot arm 41.

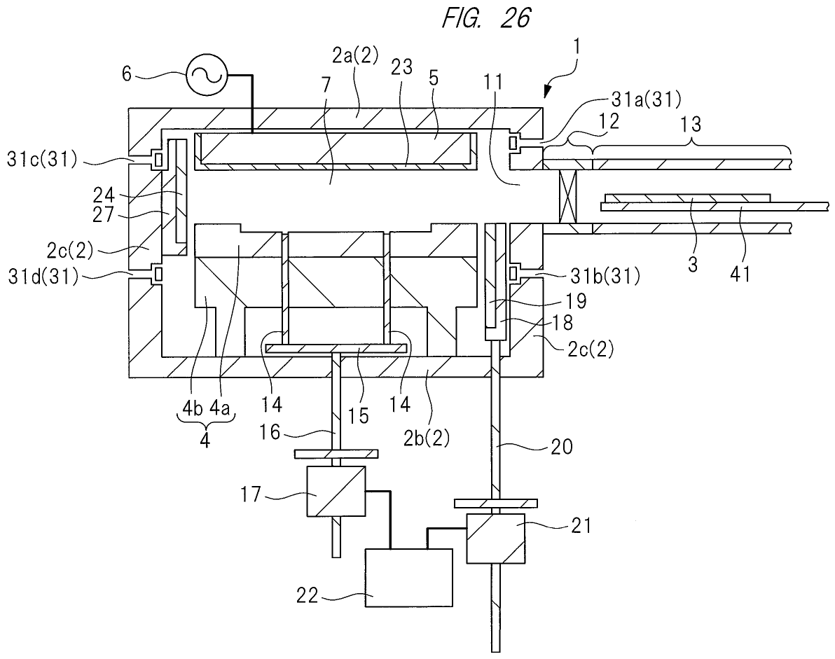

Next, as shown in FIG. 25, the robot arm 41 returns to the substrate transfer path 13 outside the chamber 2. Namely, the robot arm 41 moves to the outside of the chamber 2 through the opening 11 and the opening and closing part 12 in the open state. Since the substrate 3 is placed over the robot arm 41, the substrate 3 is unloaded to the outside of the chamber 2 (to the substrate transfer path 13) through the opening 11 and the opening and closing part 12 in the open state together with the robot arm 41. Since the support base 18 and the adhesion preventing member 19 are located at the lowered position, the upper end of the adhesion preventing member 19 and the upper end of the support base 18 are lower than the lower end of the opening 11 of the chamber 2, and the substrate 3 can be unloaded to the outside of the chamber 2 through the opening 11 without being hindered by the adhesion preventing member 19 and the support base 18. Also, since at least a part of the opening 11 of the chamber 2 is located at the same height position as the space 7 between the stage 4 (susceptor 4a) and the upper electrode 5, the substrate 3 disposed in the space 7 between the stage 4 (susceptor 4a) and the upper electrode 5 can be easily moved to the outside of the chamber 2 through the opening 11.

Next, as shown in FIG. 26, the opening and closing part 12 is closed. Thus, the opening and closing part 12 is switched from the open state to the closed state, so that the space in the chamber 2 and the space of the substrate transfer path 13 are separated by the opening and closing part 12 in the closed state.

In the step S3, the process of moving the adhesion preventing member 19 from the raised position to the lowered position (FIG. 21), the process of moving the lift pins 14 from the lowered position to the raised position (FIG. 22), and the process of opening the opening and closing part 12 (FIG. 23) are preferably performed in this order, but as another embodiment, the order thereof may be changed. However, the process of moving the adhesion preventing member 19 from the raised position to the lowered position (FIG. 21), the process of moving the lift pins 14 from the lowered position to the raised position (FIG. 22), and the process of opening the opening and closing part 12 (FIG. 23) need to be performed after the step S2 is performed and before the robot arm 41 is inserted into the chamber 2 as shown in FIG. 23.

In the manner described above, the step S3 (substrate unloading step) can be performed. By performing the step S3, the substrate 3 to which the film-forming step has been performed can be unloaded to the outside of the chamber 2. The substrate 3 unloaded from the chamber 2 to the substrate transfer path 13 is transferred to the next manufacturing apparatus for performing the next step to the substrate 3. The height position of the susceptor 4a in the chamber 2 is the same throughout the steps S1, S2, and S3.

### Background of Examination

In the film-forming apparatus (ALD apparatus) that forms a film by the ALD method, a substrate is placed over the stage in the chamber for forming a film and a desired film is formed over the substrate. Therefore, it is necessary to load the substrate which is an object to be processed into the chamber for performing the film-forming step and unload the substrate to the outside of the chamber when the film-forming step is finished.

What is examined first by the inventors of the present invention is the configuration in which the stage in the chamber is made vertically movable, the substrate is loaded into the chamber and placed over the stage located at the lowered position, the stage is then raised, and the film-forming step based on the ALD method is performed to the substrate over the stage located at the raised position. Hereinafter, this configuration is referred to as a first examination example.

However, since the stage has considerably large size and weight, the driving mechanism to vertically move the large and heavy stage becomes large and complicated in the first examination example mentioned above, and this leads to the increase in size and cost of the film-forming apparatus.

Thus, the inventors of the present invention have examined the configuration in which the substrate can be loaded into the chamber and the film-forming step can be performed to the substrate without vertically moving the stage in the chamber. In this case, the stage is fixed to the chamber, the substrate is loaded into the chamber and placed over the stage, and the film-forming step based on the ALD method is then performed to the substrate over the stage. Therefore, the height position of the stage in the chamber is constant throughout the loading of the substrate into the chamber, the film-forming step, and the unloading of the substrate from the chamber. However, the examination by the inventors of the present invention have revealed that the following problems occur in this case.

Namely, it is necessary to provide an opening for transferring a substrate (substrate transfer opening) in the chamber, and the substrate transfer opening needs to be closed during the film-forming step. Therefore, an opening and closing mechanism such as a gate valve needs to be connected to the substrate transfer opening in the chamber. However, when the stage is not made vertically movable, a substrate transfer space (space used to transfer the substrate) and a film-forming space (space used to form the film) are coincident with each other in the chamber. From another viewpoint, when the stage is not made vertically movable, the height position of the stage in the chamber is the same at the time of loading the substrate into the chamber and at the time of performing the film-forming step in the chamber, and thus the position of the substrate transfer opening in the chamber is close to the height position of the substrate at the time of performing the film-forming step. Therefore, when the film-forming step based on the ALD method is performed to the substrate over the stage in the chamber, the source gas and the reaction gas are likely to be supplied also to the substrate transfer opening and the opening and closing mechanism (gate valve) connected thereto, and thus a film is likely to be formed also over the substrate transfer opening and the opening and closing mechanism (gate valve).

In the ALD method, a film is formed over a substrate in a unit of atomic layer by alternately supplying source gas and reaction gas to the substrate. When the source gas and the reaction gas are alternately supplied to the substrate, the source gas and the reaction gas are supplied also to the substrate transfer opening of the chamber and the opening and closing mechanism (gate valve) connected thereto, and there is a concern that the film is formed also over the substrate transfer opening and the opening and closing mechanism. In particular, when the stage is not made vertically movable in the chamber, the substrate transfer opening in the chamber is located at the position where the source gas and the reaction gas are likely to be supplied also to the substrate transfer opening when supplying the source gas and the reaction gas to the substrate over the stage in the chamber.

In the case of the first examination example mentioned above, a lower part of the chamber is used as the substrate transfer space, an upper part of the chamber is used as the film-forming space, and the stage over which the substrate is placed is moved between the substrate transfer space (lower part of the chamber) and the film-forming space (upper part of the chamber). In this case, the substrate transfer space (lower part of the chamber) and the film-forming space (upper part of the chamber) are separated in the chamber and can be thus partitioned from each other. Further, the substrate transfer opening is provided to the substrate transfer space of the chamber (lower part of the chamber) and is thus away from the film-forming space of the chamber, and since the substrate transfer space (lower part of the chamber) and the film-forming space (upper part of the chamber) can be partitioned from each other, the film is less likely to be formed over the substrate transfer opening and the opening and closing mechanism (gate valve) connected thereto.

On the other hand, when the stage is not made vertically movable, since the substrate transfer space in the chamber and the film-forming space are coincident with each other, the position of the substrate transfer opening is close to the film-forming space and the film is likely to be formed also over the substrate transfer opening and the opening and closing mechanism (gate valve) connected thereto when the film-forming step based on the ALD method is performed.

When the film is formed also over the substrate transfer opening in the chamber and the opening and closing mechanism (gate valve) connected thereto, there is a concern that the following failure may occur. Namely, if the thickness of the film formed over the substrate transfer opening in the chamber and the opening and closing mechanism (gate valve) connected thereto is increased, a part of the film is peeled to be a foreign matter and this deteriorates the quality of the film formed over the substrate. Therefore, in order to improve the quality of the film formed over the substrate, it is necessary to remove the film formed over the substrate transfer opening in the chamber and the opening and closing mechanism (gate valve) connected thereto.

In this respect, for example, it is conceivable to remove the film formed over the substrate transfer opening and the opening and closing mechanism connected thereto by performing the dry etching using the cleaning gas made of NF₃ gas or the like introduced into the chamber, but the sufficient removal cannot be expected by the dry etching. Although wet etching has sufficient removing capability, it is difficult to introduce the etchant into the chamber, and it is thus difficult to clean the substrate transfer opening in the chamber and the opening and closing mechanism connected thereto by the wet etching. Also, since it is difficult to detach the substrate transfer opening in the chamber and the opening and closing mechanism (gate valve) connected thereto from the chamber, it is also difficult to detach and clean them by the wet etching. As described above, in the atomic layer deposition apparatus, there is a concern that the film is formed at the place where the removal thereof is difficult (here, the substrate transfer opening and the opening and closing mechanism connected thereto), and there is a concern that the occurrence of the foreign matter due to the peeling of the film formed at the place where the removal thereof is difficult deteriorates the quality of the film formed over the substrate.

Accordingly, it is desired that the quality of the film formed over the substrate in the chamber is improved by preventing the film from being formed over the substrate transfer opening in the chamber and the opening and closing mechanism (gate valve) connected thereto.

### Main Features and Effects

The film-forming apparatus (atomic layer deposition apparatus) 1 according to this embodiment includes the chamber 2 in which the film-forming step to the substrate 3 is performed and the stage 4 which is disposed in the chamber 2 and over which the substrate 3 is placed. The film-forming apparatus 1 further includes the substrate transfer opening 11 provided in the side wall part 2c of the chamber 2, the opening and closing part 12 disposed outside the chamber 2 and connected to the opening 11, and the movable adhesion preventing member 19 disposed in the chamber 2.

One of the main features of this embodiment is that the movable adhesion preventing member 19 is disposed in the chamber 2 and the adhesion preventing member 19 is located at the position where it covers the opening 11 in the state where the opening and closing part 12 is closed.

In this embodiment, since the movable adhesion preventing member 19 is disposed in the chamber 2, the adhesion preventing member 19 can be moved between the position where it covers the substrate transfer opening 11 and the position where it does not cover the substrate transfer opening 11. Therefore, the adhesion preventing member 19 is located at the position where it does not cover the substrate transfer opening 11 when the substrate 3 is loaded into the chamber 2 through the opening 11 and the substrate 3 is unloaded to the outside of the chamber 2 through the opening 11, and the substrate 3 can be loaded and unloaded through the opening 11 without being hindered by the adhesion preventing member 19. Also, when the film-forming step (step S2 described above) is performed to the substrate 3 in the chamber 2, the opening and closing part 12 connected to the opening 11 is closed and the adhesion preventing member 19 is located at the position where it covers the substrate transfer opening 11, so that it is possible to suppress or prevent the film from being formed over the substrate transfer opening 11 and the opening and closing part 12 connected thereto.

In the ALD method, a film is formed over the substrate 3 in a unit of atomic layer by alternately supplying source gas and reaction gas to the substrate 3. If the adhesion preventing member 19 is not provided unlike this embodiment, when the source gas and the reaction gas are alternately supplied to the substrate 3, the source gas and the reaction gas are supplied also to the substrate transfer opening 11 of the chamber 2 and the opening and closing part 12 connected thereto, and there is a concern that the film is formed also over the opening 11 and the opening and closing part 12. In this embodiment, since the adhesion preventing member 19 covers (blocks) the substrate transfer opening 11 of the chamber 2, it is possible to suppress or prevent the source gas and the reaction gas for forming the film from being supplied to the substrate transfer opening 11 of the chamber 2 and the opening and closing part 12 connected thereto, and it is possible to suppress or prevent the film from being formed over the opening 11 and the opening and closing part 12.

The adhesion preventing member 19 is easily attachable/detachable. Therefore, at the time of maintenance, the adhesion preventing member 19 can be detached, cleaned by wet cleaning (wet etching) or the like, and then attached again. Accordingly, even when the film is formed over the adhesion preventing member 19 when the film-forming step is performed to the substrate 3, the film formed over the adhesion preventing member 19 can be easily and accurately removed by the cleaning process at the time of maintenance. Therefore, since it is possible to suppress or prevent the occurrence of foreign matter due to the film formed over the substrate transfer opening 11 and the opening and closing part 12, the quality of the film formed over the substrate 3 can be improved.

In addition, the adhesion preventing member 19 is located at the position where it covers the opening 11 of the chamber 2 in the state where the opening and closing part 12 is closed. Since the substrate 3 cannot be loaded into the chamber 2 and cannot be unloaded from the chamber 2 in the state where the opening and closing part 12 is closed, the adhesion preventing member 19 does not hinder the loading and unloading of the substrate 3 even when the adhesion preventing member 19 is located at the position where it covers the opening 11 of the chamber 2. Further, by locating the adhesion preventing member 19 at the positon where it covers the opening 11 of the chamber 2, it is possible to suppress or prevent the film from being formed over the opening 11 of the chamber 2 and the opening and closing part 12 at the time of performing the film-forming step (step S2 described above) to the substrate 3 in the chamber 2. Therefore, in the film-forming apparatus 1 according to this embodiment, the adhesion preventing member 19 is located at the position where it covers the opening 11 of the chamber 2 in the state where the opening and closing part 12 is closed.

Also, in this embodiment, the loading of the substrate 3 into the chamber 2 through the opening 11 and the unloading of the substrate 3 to the outside of the chamber 2 through the opening 11 are performed in the state where the opening and closing part 12 is opened and the adhesion preventing member 19 is located at the position where it does not cover the opening 11. Accordingly, it is possible to accurately load the substrate 3 into the chamber 2 through the opening 11 and unload the substrate 3 to the outside of the chamber 2 through the opening 11 without being hindered by the opening and closing part 12 and the adhesion preventing member 19. Further, in this embodiment, the film-forming step (step S2 described above) to the substrate 3 in the chamber 2 is performed in the state where the opening and closing part 12 is closed and the adhesion preventing member 19 is located at the position where it covers the opening 11. Accordingly, it is possible to accurately form a desired film over the substrate 3 and also to accurately suppress or prevent a film from being formed over the opening 11 of the chamber 2 and the opening and closing part 12.

In addition, in this embodiment, when the film-forming step (step S2 described above) is performed to the substrate 3 in the chamber 2, at least a part of the opening 11 of the chamber 2 is located at the same height position as the space 7 between the susceptor 4a and the upper electrode 5, and the adhesion preventing member 19 covers the opening 11. If at least a part of the opening 11 of the chamber 2 is located at the same height position as the space 7 between the susceptor 4a and the upper electrode 5 when the film-forming step (step S2 described above) is performed to the substrate 3 in the chamber 2, the source gas and the reaction gas for forming a film are likely to be supplied to the opening 11 of the chamber 2 and the opening and closing part 12, and a film is likely to be formed also over the opening 11 of the chamber 2 and the opening and closing part 12. However, in this embodiment, even if at least a part of the opening 11 of the chamber 2 is located at the same height position as the space 7 between the susceptor 4a and the upper electrode 5 when the film-forming step (step S2 described above) is performed to the substrate 3 in the chamber 2, since the adhesion preventing member 19 covers the opening 11, it is possible to suppress or prevent the film from being formed over the opening 11 of the chamber 2 and the opening and closing part 12.

Also, in this embodiment, at least a part of the opening 11 of the chamber 2 is located at the same height position as the space 7 between the stage 4 (susceptor 4a) and the upper electrode 5 when loading the substrate 3 into the chamber 2 and unloading the substrate 3 to the outside of the chamber 2. Accordingly, the substrate 3 loaded into the chamber 2 through the opening 11 can be easily placed over the stage 4 (susceptor 4a), and the substrate 3 placed over the stage 4 (susceptor 4a) can be easily unloaded to the outside of the chamber 2 through the opening 11.

Also, in this embodiment, the substrate 3 can be loaded into the chamber 2, the film-forming step to the substrate 3 can be performed, and the substrate 3 can be unloaded to the outside of the chamber 2 without vertically moving the stage 4 in the chamber 2. Therefore, the stage 4 (susceptor 4a) does not move and the height position of the stage 4 (susceptor 4a) is the same in the step S1, the step S2, and the step S3 described above. Accordingly, the driving mechanism to vertically move the stage 4 becomes unnecessary, and it is possible to achieve the size and cost reduction of the film-forming apparatus 1. Also, since the total weight of the support base 18 and the adhesion preventing member 19 is smaller than the weight of the whole stage 4, the driving mechanism 21 to vertically move the support base 18 and the adhesion preventing member 19 can be made smaller than the driving mechanism required for vertically moving the stage 4. Therefore, by adopting the configuration of vertically moving the adhesion preventing mechanism 19 instead of the configuration of vertically moving the stage 4, the size and cost reduction of the film-forming apparatus 1 can be achieved.

Further, in this embodiment, since the loading of the substrate 3 into the chamber 2, the film-forming step to the substrate 3, and the unloading of the substrate 3 to the outside of the chamber 2 are performed without vertically moving the stage 4 in the chamber 2, the substrate transfer space (space used for transferring the substrate 3) in the chamber 2 and the film-forming space (space used for forming the film) are coincident with each other, and the space 7 described above corresponds to this. In the light of it, in order to easily transfer the substrate 3 through the opening 11, at least a part of the opening 11 of the chamber 2 is located at the same height position as the space 7 between the stage 4 (susceptor 4a) and the upper electrode 5, and this state is maintained in the step S1, the step S2, and the step S3 described above. Therefore, the opening 11 of the chamber 2 is located at the position where a film is likely to be formed at the time of the film-forming step to the substrate 3. However, in this embodiment, the opening 11 located at such a position is covered with the adhesion preventing member 19, so that it is possible to form the desired film over the substrate 3 and also possible to suppress or prevent the film from being formed over the opening 11 of the chamber 2 and the opening and closing part 12.

Also, in the step S2 described above, the first step, the second step, the third step, and the fourth step are performed while supplying the inert gas into the chamber 2 through the inert gas introduction part 31. The inert gas introduced (supplied) into the chamber 2 through the inert gas introduction parts 31a and 31b is supplied to the surface of the adhesion preventing member 19. Specifically, the inert gas introduced into the chamber 2 through the inert gas introduction part 31a mainly flows to the space 7 through the gap between the adhesion preventing member 19 and the adhesion preventing member 23 and is exhausted through the gas exhaust part 9. Also, the inert gas introduced into the chamber 2 through the inert gas introduction part 31b mainly flows to the space 7 through the gap between the adhesion preventing member 19 and the stage 4 (susceptor 4a) and is exhausted through the gas exhaust part 9. In this manner, since it is possible to suppress or prevent the source gas and the reaction gas from being diffused through the gap between the adhesion preventing member 19 and the adhesion preventing member 23 and the gap between the adhesion preventing member 19 and the stage 4 (susceptor 4a), it is possible to easily suppress or prevent the formation of the unnecessary film over the chamber 2 and the stage 4.

In addition, the inert gas introduced (supplied) into the chamber 2 through the inert gas introduction parts 31c and 31d is supplied to the surface of the adhesion preventing member 24. Specifically, the inert gas introduced into the chamber 2 through the inert gas introduction part 31c mainly flows to the space 7 through the gap between the adhesion preventing member 24 and the adhesion preventing member 23 and is exhausted through the gas exhaust part 9. Also, the inert gas introduced into the chamber 2 through the inert gas introduction part 31d mainly flows to the space 7 through the gap between the adhesion preventing member 24 and the stage 4 (susceptor 4a) and is exhausted through the gas exhaust part 9. In this manner, since it is possible to suppress or prevent the source gas and the reaction gas from being diffused through the gap between the adhesion preventing member 24 and the adhesion preventing member 23 and the gap between the adhesion preventing member 24 and the stage 4 (susceptor 4a), it is possible to easily suppress or prevent the formation of the unnecessary film over the chamber 2 and the stage 4.

In addition, the inert gas introduced (supplied) into the chamber 2 through the inert gas introduction parts 31e and 31f is supplied to the surface of the adhesion preventing member 25. Specifically, the inert gas introduced into the chamber 2 through the inert gas introduction part 31e mainly flows to the space 7 through the gap between the adhesion preventing member 25 and the adhesion preventing member 23 and is exhausted through the gas exhaust part 9. Also, the inert gas introduced into the chamber 2 through the inert gas introduction part 31f mainly flows to the space 7 through the gap between the adhesion preventing member 25 and the stage 4 (susceptor 4a) and is exhausted through the gas exhaust part 9. In this manner, since it is possible to suppress or prevent the source gas and the reaction gas from being diffused through the gap between the adhesion preventing member 25 and the adhesion preventing member 23 and the gap between the adhesion preventing member 25 and the stage 4 (susceptor 4a), it is possible to easily suppress or prevent the formation of the unnecessary film over the chamber 2 and the stage 4.

In addition, the inert gas introduced (supplied) into the chamber 2 through the inert gas introduction parts 31g and 31h is supplied to the surface of the adhesion preventing member 26. Specifically, the inert gas introduced into the chamber 2 through the inert gas introduction part 31g mainly flows to the space 7 through the gap between the adhesion preventing member 26 and the adhesion preventing member 23 and is exhausted through the gas exhaust part 9. Also, the inert gas introduced into the chamber 2 through the inert gas introduction part 31h mainly flows to the space 7 through the gap between the adhesion preventing member 26 and the stage 4 (susceptor 4a) and is exhausted through the gas exhaust part 9. In this manner, since it is possible to suppress or prevent the source gas and the reaction gas from being diffused through the gap between the adhesion preventing member 26 and the adhesion preventing member 23 and the gap between the adhesion preventing member 26 and the stage 4 (susceptor 4a), it is possible to easily suppress or prevent the formation of the unnecessary film over the chamber 2 and the stage 4.

Also, various material films can be selectively used as the films to be formed over the substrate 3 in the step S2 described above. However, the effect is significantly large if the film-forming apparatus 1 according to this embodiment is used when the film to be formed over the substrate 3 in the step S2 described above is an aluminum oxide film (typically, Al₂O₃ film), a hafnium oxide film (typically, HfO₂ film), a tantalum oxide film (typically, Ta₂O₅ film), a titanium oxide film (typically, TiO₂ film), or a zirconium oxide film (typically, ZrO₂ film). This is because an aluminum oxide film, a hafnium oxide film, a tantalum oxide film, a titanium oxide film, or a zirconium oxide film is hardly removed by the cleaning using dry etching. In this case, the formation of the unnecessary film over the opening 11 of the chamber 2 and the opening and closing part 12 can be prevented by the adhesion preventing member 19, and the unnecessary film formed over the adhesion preventing member 19 can be easily and accurately removed by detaching the adhesion preventing member 19 and performing the cleaning process using wet cleaning (wet etching) at the time of maintenance.

### Application Example of Film-Forming Step

The film formed over the substrate 3 in the step S2 can be formed as a film constituting a part of a protection film that protects a light-emitting layer of an organic EL element. In this case, the substrate 3 is, for example, a glass substrate or a flexible substrate. In particular, since an aluminum oxide film is excellent as a protection film for an organic EL element, an aluminum oxide film can be formed over the substrate 3 as the protection film for an organic EL element in the step S2. For example, by using TMA gas as the source gas, oxygen gas as the reaction gas, and nitrogen gas as the purge gas, an aluminum oxide film can be formed over the substrate 3.

Also, the film formed over the substrate 3 in the step S2 can be formed as a film constituting a gate insulating film of a field effect transistor (semiconductor element). In this case, the substrate 3 is, for example, a semiconductor substrate, and various types of films typified by a silicon oxide film can be used as the film formed over the substrate 3 in addition to an aluminum oxide film, a hafnium oxide film, a tantalum oxide film, a titanium oxide film, and a zirconium oxide film.

In the foregoing, the invention made by the inventors of the present invention has been concretely described based on the embodiments. However, it is needless to say that the present invention is not limited to the foregoing embodiments and various modifications can be made within the scope of the present invention.

What is claimed is:

1. An atomic layer deposition apparatus, comprising:
a chamber in which a film-forming step is performed to a substrate;
a stage which is disposed in the chamber and over which the substrate is placed;
an opening which is provided in a side wall of the chamber and is used to transfer the substrate;
an opening and closing part which is disposed outside the chamber and is connected to the opening; and
a movable first adhesion preventing member disposed in the chamber,
wherein the first adhesion preventing member is located at a position where it covers the opening in a state where the opening and closing part is closed.

2. The atomic layer deposition apparatus according to claim 1, further comprising:
a susceptor disposed over the stage; and
an electrode which is disposed in the chamber and generates a high frequency electric field between the electrode and the susceptor,
wherein the substrate is placed over the susceptor.

3. The atomic layer deposition apparatus according to claim 1,
wherein the first adhesion preventing member is movable inside the chamber along the side wall of the chamber.

4. The atomic layer deposition apparatus according to claim 1, further comprising
a raising and lowering mechanism disposed outside the chamber,
wherein the first adhesion preventing member is raised and lowered by the raising and lowering mechanism.

5. The atomic layer deposition apparatus according to claim 1,
wherein a gas supply part for supplying source gas, purge gas, and reaction gas into the chamber is formed in the side wall of the chamber.

6. The atomic layer deposition apparatus according to claim 5,
wherein a gas exhaust part for exhaustion is formed in the side wall of the chamber.

7. The atomic layer deposition apparatus according to claim 6,
wherein the gas supply part and the gas exhaust part are located at positions facing each other in the side wall of the chamber.

8. The atomic layer deposition apparatus according to claim 6,
wherein the side wall of the chamber has a pair of first side surfaces facing each other and a pair of second side surfaces facing each other,
the opening is formed in one of the pair of first side surfaces,
the gas supply part is formed in one of the pair of second side surfaces, and
the gas exhaust part is formed in the other of the pair of second side surfaces.

9. The atomic layer deposition apparatus according to claim 8,
wherein the pair of first side surfaces and the pair of second side surfaces are orthogonal to each other.

10. The atomic layer deposition apparatus according to claim 1,
wherein a first inert gas supply port is formed in the side wall of the chamber, and
inert gas can be supplied to a surface of the first adhesion preventing member through the first inert gas supply port in a state where the first adhesion preventing member covers the opening.

11. The atomic layer deposition apparatus according to claim 10,
wherein a plurality of the first inert gas supply ports are formed above and below the opening.

12. The atomic layer deposition apparatus according to claim 2,
wherein the side wall of the chamber has a pair of first side surfaces facing each other and a pair of second side surfaces facing each other,
the opening is formed in one of the pair of first side surfaces,
a second adhesion preventing member is disposed on a side closer to the other of the pair of first side surfaces, and
the second adhesion preventing member and the first adhesion preventing member located at the position where it covers the opening face each other with the susceptor and the electrode interposed therebetween.

13. The atomic layer deposition apparatus according to claim 2,
wherein a third adhesion preventing part is disposed so as to cover a main surface and a side surface of the electrode.

14. The atomic layer deposition apparatus according to claim 12,
wherein a second inert gas supply port is formed in the other of the pair of first side surfaces of the chamber, and
inert gas can be supplied to a surface of the second adhesion preventing member through the second inert gas supply port.

15. The atomic layer deposition apparatus according to claim 2, further comprising
lift pins penetrating the susceptor,
wherein the substrate can be raised and lowered by the lift pins.

16. The atomic layer deposition apparatus according to claim 1,
wherein the substrate is a semiconductor substrate, a glass substrate, or a flexible substrate.

17. The atomic layer deposition apparatus according to claim 2,
wherein when the film-forming step is performed to the substrate, at least a part of the opening of the chamber is located at the same height as a space between the susceptor and the electrode, and the first adhesion preventing member covers the opening.

18. The atomic layer deposition apparatus according to claim 1,
wherein in a state where the opening and closing part is opened and the first adhesion preventing member is located at a position where it does not cover the opening, the substrate is loaded into the chamber through the opening, and
in a state where the opening and closing part is closed and the first adhesion preventing member is located at the position where it covers the opening, the film-forming step to the substrate in the chamber is performed.

19. A film-forming method by an atomic layer deposition method comprising the steps of:
(a) loading a substrate into a chamber through an opening of the chamber;
(b) after the step (a), closing an opening and closing part disposed outside the chamber and connected to the opening;
(c) after the step (a), moving an adhesion preventing member disposed in the chamber to a position where it covers the opening; and
(d) after the step (b) and the step (c), forming a film over the substrate in the chamber by the atomic layer deposition method.

20. The film-forming method according to claim 19,
wherein in the step (d), the film is formed by repeating the steps of:
(d1) introducing source gas into the chamber;
(d2) after the step (d1), introducing first purge gas into the chamber;
(d3) after the step (d2), introducing reaction gas into the chamber; and
(d4) after the step (d3), introducing second purge gas into the chamber, in plural cycles.

21. The film-forming method according to claim 20,
wherein in the step (d4), the reaction gas is converted into plasma by a high frequency power.

22. The film-forming method according to claim 21,
wherein in the step (a), the substrate loaded into the chamber is placed over a susceptor in the chamber,
in the step (d4), the high frequency power is applied between an electrode disposed above the susceptor and the susceptor in the chamber, and
in the step (d), at least a part of the opening of the chamber is located at the same height as a space between the susceptor and the electrode.

23. The film-forming method according to claim 19,
wherein in the step (a), the substrate loaded into the chamber is placed over a susceptor in the chamber, and
in the step (a), the step (b), the step (c), and the step (d), a height position of the susceptor is the same.

24. The film-forming method according to claim 19, further comprising the steps of:
(e) after the step (d), moving the adhesion preventing member in the chamber to a position where it does not cover the opening;
(f) after the step (d), opening the opening and closing part; and
(g) after the step (e) and the step (f), unloading the substrate to outside of the chamber through the opening of the chamber.

25. The film-forming method according to claim 19,
wherein the film formed over the substrate in the step (d) is an aluminum oxide film, a hafnium oxide film, a tantalum oxide film, a titanium oxide film, or a zirconium oxide film.
